(19) United States
(12) Patent Application Publication
(10) Pub. No.: US 2026/0042162 A1
(43) Pub. Date: Feb. 12, 2026

(54) ELECTRICAL DISCHARGE MACHINING APPARATUS AND METHOD OF THE SAME

(71) Applicant: HIGHLIGHT TECH CORP., Tainan City (TW)

(72) Inventors: CHWUNG-SHAN KOU, Tainan City (TW); WEN-YUNG YEH, Tainan City (TW); CHANG-YING CHEN, Tainan City (TW)

(73) Assignee: HIGHLIGHT TECH CORP., Tainan City (TW)

(21) Appl. No.: 18/747,574

(22) Filed: Jun. 19, 2024

(30) Foreign Application Priority Data
Apr. 19, 2024 (TW) 113114788

(51) Int. Cl. B23H 1/02; H01L 21/326

(52) U.S. Cl. CPC B23H 1/02; H01L 21/326

(57) ABSTRACT

Disclosed are an electrical discharge machining apparatus and a method of the same used for performing an electrical discharge machining procedure on a to-be-machined object. The electrical discharge machining apparatus comprises a carrier and an electrical discharge machining unit. The electrical discharge machining unit performs the electrical discharge machining procedure on a machining target area of the to-be-machined object through an electrical discharge electrode with a machining parameter. The electrical discharge machining unit adjusts an actual output energy value correspondingly according to a changing status of an electrical discharge frequency or energy during an electrical discharge process of the electrical discharge machining procedure, so that the electrical discharge machining procedure maintains in a target machining status. The electrical discharge machining apparatus and the method of the same use a debris removal unit to provide an external force to assist in removing debris remaining in a machining groove.

### CROSS-REFERENCE TO RELATED APPLICATION

This application claims priority from Taiwan Patent Application No. 113114788, filed on Apr. 19, 2024, each of which is hereby incorporated herein by reference in its entireties.

### BACKGROUND OF THE DISCLOSURE

### 1. Field of Disclosure

The disclosure relates to a machining apparatus and a method, more particularly to an electrical discharge machining apparatus and a method of the same.

### 2. Related Art

With the booming semiconductor industry, electrical discharge machining (EDM) technology has been commonly used to machine ingots or wafers. Electrical discharge machining is a manufacturing process wherein sparks are generated by electrical discharge, thereby a desired shape of a to-be-machined object can be obtained. A dielectric material separates two electrodes and a voltage is applied to generate rapidly recurring current discharges between the two electrodes to machine the to-be-machined object. Electrical discharge machining technology uses two electrodes, one of which is called the tool electrode, or the electrical discharge electrode, while the other is called the workpiece electrode, connected to the to-be-machined object. During electrical discharge machining, there is no physical contact between the electrical discharge electrode and the workpiece electrode.

When the potential difference between the two electrodes is increased, the electric field between the two electrodes becomes greater until the intensity of the electric field exceeds the dielectric strength, causing dielectric breakdown, current flows through the two electrodes, and part of the material is removed. Once the current stops, new dielectric material is conveyed into the inter-electrode electric field, enabling the partial material to be carried away and restoring the dielectric insulating effect. After a current flow, the potential difference between the two electrodes is restored to what it was before the dielectric break down, so that a new dielectric breakdown can occur to repeat the cycle. Since the above-mentioned electrical discharge machining procedure will remove part of a material of the to-be-machined object, the separation distance between the electrode and the to-be-machined object will become larger. When the separation distance continues to increase until the electric field intensity is lower than the dielectric strength, it will cause a situation where electrical discharge cannot be performed, that is, causing the electrical discharge machining procedure to be interrupted. Therefore, during the feeding process of electrical discharge machining, it is required to continuously adjust (reduce or increase) the above-mentioned separation distance in real time. However, in existing technologies, it is not possible to directly measure the above-mentioned separation distance, and the operator's experience can only be relied on to adjust the separation distance for various to-be-machined objects.

The roughness of the cut surface formed by the existing electrical discharge machining technology is not ideal, and there are quite a few surface cracks on the cut surface, which even extend along the non-cut direction, resulting in cracking effect in an unexpected direction. Moreover, in the existing electrical discharge machining technology, for example, when cutting an ingot, a jig is used to clamp a periphery of the ingot, that is, the side edge of the ingot is radially clamped to prevent rolling or displacement. However, the conventional technology can only cut the ingot exposed on the outer side of the jig, and cannot cut the area where the jig and the ingot overlap, so in the conventional technology, the machine or apparatus needs to be shut down to readjust a position to enable cutting again.

Moreover, in the traditional ingot cutting technology, because a thickness of the cut wafer is quite thin, wafer cracking often occurs in the traditional ingot cutting technology. In addition, in the traditional electrical discharge machining technology, it is easy for the electrical discharge electrode to adhere debris, resulting in uneven electrical discharge (such as discharge cessation or excessive local current), and even damage to the electrode and the to-be-machined object.

### SUMMARY OF THE DISCLOSURE

In view of the above-mentioned problems of the conventional techniques, an object of the disclosure is to provide an electrical discharge machining apparatus and a method of the same to solve the above-mentioned problems of the traditional technologies.

In order to achieve the aforementioned object, the disclosure discloses an electrical discharge machining apparatus for performing an electrical discharge machining procedure on at least one to-be-machined object, comprising: at least one carrier for carrying the to-be-machined object, the to-be-machined object is defined with at least one machining target area; and at least one electrical discharge machining unit, comprising at least one electrical discharge electrode and a power supply unit, wherein the power supply unit provides an electrical discharge energy to the electrical discharge electrode with an electrical discharge frequency, and the electrical discharge machining unit performs the electrical discharge machining procedure on the machining target area of the to-be-machined object through the electrical discharge electrode with at least one machining parameter, wherein the electrical discharge machining unit adjusts an actual output energy value correspondingly according to a changing status of the electrical discharge frequency or the electrical discharge energy during an electrical discharge process of the electrical discharge machining procedure, so that the electrical discharge machining procedure maintains in a target machining status.

Preferably, the electrical discharge machining unit adjusts the electrical discharge frequency and/or the electrical discharge energy provided by the power supply unit in order to adjust the actual output energy value in real time when performing the electrical discharge machining procedure, so that the electrical discharge machining procedure is maintained in the target machining status.

Preferably, the electrical discharge machining unit adjusts the actual output energy value in real time accordingly by adjusting the machining parameter.

Preferably, the electrical discharge machining unit correspondingly adjusts the machining parameter according to an intrinsic or extrinsic characteristic of the to-be-machined object, so that the electrical discharge machining procedure is maintained in the target machining status.

Preferably, there are a plurality of types of the machining parameter, and the electrical discharge machining procedure selects at least one of the types of the machining parameters for adjustment, so that the electrical discharge machining procedure is maintained in the target machining status.

Preferably, the target machining status is selected from a group consisting of the cutting speed, material removal rate, material loss rate and surface roughness of the to-be-machined object, and disconnection frequency of the electrical discharge electrode.

Preferably, the electrical discharge machining unit performs the electrical discharge machining procedure on the machining target area of the to-be-machined object at a preset temperature, and the preset temperature is less than or equal to 100 degrees Celsius.

Preferably, the electrical discharge machining unit performs the electrical discharge machining procedure on the machining target area of the to-be-machined object in a temperature range, wherein the to-be-machined object has a substantially lowest resistivity in the temperature range.

Preferably, the electrical discharge machining unit performs the electrical discharge machining procedure on the machining target area of the to-be-machined object in an aqueous solution.

Preferably, the to-be-machined object is a semiconductor material.

Preferably, the carrier further comprises at least one clamping element, the clamping element is a slit structure, and the clamping element exerts a force radially or axially on the to-be-machined object to fix the to-be-machined object.

Preferably, a shape of a slit of the slit structure is selected from a group consisting of closed type without opening, single-sided opening type and double-sided opening type.

Preferably, the clamping element is a fixed or detachable single-sided lock-in structure or double-sided lock-in structure for clamping the to-be-machined object.

Preferably, the slit structure has one slit or a plurality of slits, and each of the slits has a same span or different spans.

Preferably, the slit structure has one slit or a plurality of slits, and a spacing between the every two adjacent slits is the same or different.

Preferably, the slit structure has at least one slit, and the slit has a non-equidistant span or an adjustable span.

Preferably, the slit structure has a plurality of slits, and at least two of the slits in the slits are communicated to each other.

Preferably, the clamping element and the to-be-machined object are partially connected or bonded to each other through a conductor or an insulator.

Preferably, the conductor or the insulator is a solid medium, a soft medium or an adhesive.

Preferably, the electrical discharge machining apparatus further comprises a debris removal unit for providing at least one external force to remove debris generated when the electrical discharge electrode performing the electrical discharge machining procedure on the to-be-machined object.

Preferably, the external force is selected from one or more than one of a group consisting of air flow, water flow, ultrasonic oscillation, piezoelectric oscillation, suction force and magnetic force.

Preferably, the debris removal unit further comprises a guide structure for guiding the external force to reach a machining groove on the machining target area of the to-be-machined object performed with the electrical discharge machining procedure by the electrical discharge electrode.

Preferably, the guide structure manually or automatically changes position or angle of guiding the external force along with the electrical discharge electrode performing the electrical discharge machining procedure, so as to guide the external force to reach an electrical discharge machining position of the machining groove of the to-be-machined object in the electrical discharge machining procedure currently performed by the electrical discharge electrode.

Preferably, the guide structure moves a position in the machining groove of the machining target area of the to-be-machined object along with the electrical discharge electrode, thereby moving in a synchronous filling manner to reach an electrical discharge machining position on the machining groove of the machining target area where the electrical discharge machining procedure has been completed.

Preferably, the guide structure is an externally sealed baffle used for covering an area of the machining target area of the to-be-machined object that has not yet been processed by the electrical discharge machining procedure, and moving a position synchronously along with the electrical discharge electrode.

Preferably, the guide structure is an interdigitated structure corresponding to the machining groove on the machining target area of the to-be-machined object.

Preferably, the guide structure is used in conjunction with a telescopic mechanism, so as to automatically move synchronously along with the electrical discharge electrode to guide the external force.

Preferably, the guide structure is used in conjunction with a sensing element for adjusting a guiding effect of the guide structure based on a sensing result of the sensing element.

Preferably, the electrical discharge machining apparatus further comprises a temperature control unit for providing a heat source and/or a cold source when performing the electrical discharge machining procedure to directly or indirectly adjust a temperature of the to-be-machined object.

Preferably, the heat source is infrared ray, microwave or electric heater.

Preferably, the cold source is used in conjunction with an antifreeze agent to prevent a machining environment of the electrical discharge machining unit from freezing.

Preferably, the temperature control unit has a temperature sensor to judge whether a machining environment of the to-be-machined object reaches a target temperature to maintain the machining environment at the target temperature.

Preferably, a machining environment of the electrical discharge machining unit is added with ozone or bubbles, thereby improving a machining efficiency through oxidation, softening or bursting.

Preferably, a material of the electrical discharge electrode is selected from a group consisting of copper, brass, molybdenum, tungsten, graphite, steel, aluminum, zinc, nickel and diamond.

Preferably, an interior of the electrical discharge electrode is a metal layer, and the electrical discharge electrode has a dielectric material layer or a diamond layer covering an outer periphery of the metal layer.

Preferably, during the electrical discharge process of the electrical discharge machining procedure, the electrical discharge electrode serves as a capacitive sensing element for providing a sensing capacitance value.

Preferably, when a number of at least either the electrical discharge electrode or the to-be-machined object is a plurality, the electrical discharge machining procedure has a plurality of machining feed speeds correspondingly, and the electrical discharge machining unit uses a slowest one among the machining feed speeds as a common machining feed speed.

Preferably, the carrier is a movable carrier, and the carrier uses the common machining feed speed as a moving speed.

Preferably, a number of the electrical discharge electrode is a plurality, and each of the electrical discharge electrodes has an independently controlled machining feed speed.

Preferably, numbers of the electrical discharge electrode and the to-be-machined object are a plurality, and the electrical discharge electrodes perform the electrical discharge machining procedure on the same to-be-machined object or the different to-be-machined objects.

Preferably, the electrical discharge machining unit further comprises an insulating sleeve, and the insulating sleeve is sleeved on an outer side of the electrical discharge electrode and exposes at least one surface of the electrical discharge electrode in a machining feed direction, thereby using the surface as an electrical discharge surface when the electrical discharge electrode performs the electrical discharge process.

Preferably, an electrical discharge area formed by the electrical discharge surface exposed by the electrical discharge electrode during performing the electrical discharge process is substantially greater than a cross section of the insulating sleeve.

Preferably, relative positions of the insulating sleeve and the electrical discharge electrode in a machining feed direction of the electrical discharge machining procedure are fixed, and relative positions of the insulating sleeve and the electrical discharge electrode in a tension direction of the electrical discharge electrode are movable.

Preferably, the insulating sleeve comprises a bottom plate and two side walls, the two side walls are located at two ends of the bottom plate to form a trough, an interior of the trough forms a chamber for accommodating the electrical discharge electrode, and the trough has an opening communicated to the chamber for exposing the electrical discharge surface of the electrical discharge electrode located in the chamber.

Preferably, the insulating sleeve is sleeved on an outer side of the electrical discharge electrode along a tension direction of the electrical discharge electrode, and the insulating sleeve has one notch or a plurality of notches for providing a function of draining water or removing debris in the electrical discharge machining procedure.

Preferably, the carrier further comprises at least one clamping element, and a degree of conformity between a clamping surface of the clamping element and a contour of the to-be-machined object is correspondingly changed based on a degree of clamping between the clamping element and the to-be-machined object in order to correspondingly change a degree of adhesion between the clamping surface of the clamping element and the contour of the to-be-machined object.

Preferably, the power supply unit of the electrical discharge machining unit is integratedly or detachably configured on the electrical discharge machining apparatus for supplying a power source of the electrical discharge energy to the to-be-machined object.

Preferably, the electrical discharge machining apparatus further comprises a non-destructive detection device for detecting the to-be-machined object before, during or after performing the electrical discharge machining procedure.

Preferably, the electrical discharge machining unit further comprises a vibration measuring unit for measuring a vibration value of the electrical discharge electrode.

Preferably, the electrical discharge machining unit further comprises a tension measuring unit for measuring a tension value of the electrical discharge electrode.

In order to achieve the aforementioned object, the disclosure further discloses an electrical discharge machining method using the above-mentioned electrical discharge machining apparatus, comprising following steps of: providing a carrier; providing a to-be-machined object, wherein the to-be-machined object is defined with a machining target area, and the to-be-machined object is carried on the carrier; and providing an electrical discharge machining unit, the electrical discharge machining unit comprises at least one electrical discharge electrode and a power supply unit, wherein the power supply unit provides an electrical discharge energy to the electrical discharge electrode with an electrical discharge frequency, and the electrical discharge machining unit performs an electrical discharge machining procedure on the machining target area of the to-be-machined object through the electrical discharge electrode with a machining parameter, wherein the electrical discharge machining unit adjusts an actual output energy value correspondingly according to a changing status of the electrical discharge frequency or the electrical discharge energy during an electrical discharge process of the electrical discharge machining procedure, so that the electrical discharge machining procedure maintains in a target machining status.

Based on above, the electrical discharge machining apparatus and the method of the same of the disclosure have the following advantages and efficacies:

(1) According to a changing status of the electrical discharge frequency or the electrical discharge energy during the electrical discharge process, an actual electrical discharge energy value of the electrical discharge process could be adjusted correspondingly, so that the electrical discharge machining procedure could be maintained in a predetermined target machining status.

(2) A debris removal unit could provide an external force to assist in removing debris remaining in a machining groove.

(3) A guide structure could correctly guide the external force provided by the debris removal unit to a current electrical discharge machining position of the electrical discharge machining procedure.

(4) The electrical discharge electrode could be used as a capacitive sensing element to provide a sensing capacitance value as an electrical discharge feedback signal in real time.

(5) An insulating sleeve covers the electrical discharge electrode and exposes an electrical discharge surface of the electrical discharge electrode in a machining feed direction, which could reduce kerf loss and improve a precision of electrical discharge machining, so it could effectively improve the problem that the traditional electrical discharge electrodes and a to-be-machined object are prone to unexpected damage.

(6) Covering the electrical discharge electrode with the insulating sleeve could make the electrical discharge electrode less shaken and could also enhance the external force (such as water flow or air flow) to achieve an effect of removing debris. The insulating sleeve could make the to-be-machined object (such as wafer) less shaken after cutting, reducing the risk of fragmentation.

Moreover, the insulating sleeve could use the external force (such as water flow or air flow) for removing debris to reduce a friction between the insulating sleeve and the electrical discharge electrode to avoid damage to the electrical discharge electrode. In addition, the insulating sleeve could also provide an efficacy of local heating.

(7) The insulating sleeve has a gap, which not only improves an electrical discharge machining effect of the electrical discharge electrode, but also provides a debris removal function.

(8) A clamping element has a slit structure that could firmly clamp the to-be-machined object, and could effectively solve the problem that the traditional electrical discharge machining technologies cannot cut an overlapping area between the clamping element and the to-be-machined object, and a lock-in structure could further achieve efficacies of disassembly, assembly and adjustment.

(9) The clamping element could be connected or adhered to the to-be-machined object through a buffer member, which could effectively avoid wafer cracking that often occurs in the traditional ingot cutting technologies.

In order to enable the examiner to have a further understanding and recognition of the technical features of the disclosure, preferred embodiments in conjunction with detailed explanation are provided as follows.

### BRIEF DESCRIPTION OF THE DRAWINGS

FIG. 1 is a front view of an electrical discharge machining apparatus of the disclosure, which shows that a carrier carries a to-be-machined object through a bearing plate.

FIG. 2 is a front view of the electrical discharge machining apparatus of the disclosure, which shows that the carrier carries the to-be-machined object through a clamping element.

FIG. 3 is a top view of the electrical discharge machining apparatus of the disclosure, which shows that the carrier carries the to-be-machined object through the clamping element, wherein FIG. 3(A) and FIG. 3(B) show that a span of a slit could be adjusted correspondingly by different thicknesses of a gasket.

FIG. 4 is a cross-sectional view of an electrical discharge electrode of the electrical discharge machining apparatus of the disclosure, in which FIG. 4(A) shows that the electrical discharge electrode is composed of a metal layer, FIG. 4(B) shows that the electrical discharge electrode is composed of a metal layer and a diamond layer, and FIG. 4(C) shows that the electrical discharge electrode is composed of a metal layer and a dielectric material layer.

FIG. 5 is a top view of the electrical discharge electrode of the electrical discharge machining apparatus of the disclosure covered with an insulating sleeve, wherein FIG. 5(A) and FIG. 5(C) show that a machining groove has not yet been formed, and FIG. 5(B) shows that the machining groove has been formed.

FIG. 6 is a front view of the electrical discharge electrode of the electrical discharge machining apparatus of the disclosure covered with the insulating sleeve, wherein FIGS. 6(A) and 6(C) show that the machining groove has not yet been formed, and FIG. 6(B) shows that the machining groove has been formed.

FIG. 7 is a top view of the electrical discharge machining apparatus of the disclosure performing an electrical discharge machining procedure in a tank.

FIG. 8 is a top view of a slit structure of the electrical discharge machining apparatus of the disclosure, with the slits communicating with one another.

FIG. 9 is a top view of the slit structure of the electrical discharge machining apparatus of the disclosure, with a form of the slit being a closed type without opening, in which FIG. 9(B) further has an auxiliary hole compared to FIG. 9(A).

FIG. 10 is a top view of the slit structure of the electrical discharge machining apparatus of the disclosure, with a form of the slit being a single-sided opening type, in which FIG. 10(A), FIG. 10(B) and FIG. 10(C) respectively show modes of the clamping element being located above and on a side of the carrier.

FIG. 11 is a top view of the slit structure of the electrical discharge machining apparatus of the disclosure, with the slit having a guide groove, in which FIG. 11(A), FIG. 11(B) and FIG. 11(C) respectively show modes of the clamping element being located above and on a side of the carrier.

FIG. 12 is a front view of the clamping element of the electrical discharge machining apparatus of the disclosure being a single-sided lock-in structure, in which FIGS. 12(A) and 12(B) respectively show two modes of the clamping element.

FIG. 13 is a front view of the clamping element of the electrical discharge machining apparatus of the disclosure using the buffer member to indirectly clamp the to-be-machined object.

FIG. 14 is a side view of the clamping element of the electrical discharge machining apparatus of the disclosure clamping the to-be-machined object, in which FIG. 14(A) shows that the clamping element directly clamps the to-be-machined object, and FIG. 14(B) shows that the clamping element indirectly clamps the to-be-machined object.

FIG. 15 is a front view of the electrical discharge machining apparatus of the disclosure having a debris removal unit.

FIG. 16 is a front view of the debris removal unit of the electrical discharge machining apparatus of the disclosure performing a debris removal action, in which FIGS. 16(A) and 16(B) show that the debris removal unit uses different debris removal modes to perform the debris removal action.

FIG. 17 is a front view of the debris removal unit of the electrical discharge machining apparatus of the disclosure having a guide structure.

FIG. 18 is a front view of the guide structure of the electrical discharge machining apparatus of the disclosure being an externally enclosed baffle.

FIG. 19 is a front view of the guide structure of the electrical discharge machining apparatus of the disclosure being an interdigitated structure.

FIG. 20 is a front view of the guide structure of the electrical discharge machining apparatus of the disclosure being an arc-shaped structure.

FIG. 21 is a front view of the guide structure of the electrical discharge machining apparatus of the disclosure used in conjunction with a telescopic mechanism to perform a guide action.

FIG. 22 is a front view of the guide structure of the electrical discharge machining apparatus of the disclosure used in conjunction with a sensing element to perform a debris removal detection.

### DETAILED DESCRIPTION OF THE DISCLOSURE

In order to understand the technical features, content and advantages of the disclosure and its achievable efficacies, the disclosure is described below in detail in conjunction with the figures, and in the form of embodiments, the figures used herein are only for a purpose of schematically supplementing the specification, and may not be true proportions and precise configurations after implementation of the disclosure; and therefore, relationship between the proportions and configurations of the attached figures should not be interpreted to limit the scope of the claims of the disclosure in actual implementation. In addition, in order to facilitate understanding, the same elements in the following embodiments are indicated by the same referenced numbers. And the size and proportions of the components shown in the drawings are for the purpose of explaining the components and their structures only and are not intending to be limiting.

Unless otherwise noted, all terms used in the whole descriptions and claims shall have their common meaning in the related field in the descriptions disclosed herein and in other special descriptions. Some terms used to describe in the present disclosure will be defined below or in other parts of the descriptions as an extra guidance for those skilled in the art to understand the descriptions of the present disclosure.

The terms such as “first”, “second”, “third”, “fourth” used in the descriptions are not indicating an order or sequence, and are not intending to limit the scope of the present disclosure. They are used only for differentiation of components or operations described by the same terms.

Moreover, the terms “comprising”, “including”, “having”, and “with” used in the descriptions are all open terms and have the meaning of “comprising but not limited to”.

The disclosure discloses an electrical discharge machining apparatus and a method of the same for performing an electrical discharge machining procedure on at least one to-be-machined object. In the disclosure, the electrical discharge machining apparatus and the method of the same are capable of maintaining the electrical discharge machining procedure in a predetermined target machining status by improving an electrical discharge machining unit. For example, the electrical discharge machining unit is capable of adjusting an actual electrical discharge energy of an electrical discharge process in real time correspondingly according to a changing status of an electrical discharge frequency or an electrical discharge energy during the electrical discharge process of the electrical discharge machining procedure. The disclosure is capable of intelligently adjusting the electrical discharge energy (such as actual output energy), so that the electrical discharge machining procedure could be maintained in the predetermined target machining status (such as maintaining cutting speed, maintaining maximum material removal rate (MRR), maintaining no disconnection, maintaining predetermined surface roughness, maintaining predetermined disconnection frequency or other statuses). In addition, the electrical discharge machining apparatus and the method of the same of the disclosure are capable of further improving an electrical discharge machining efficiency by improving structural designs of the electrical discharge machining unit and a carrier.

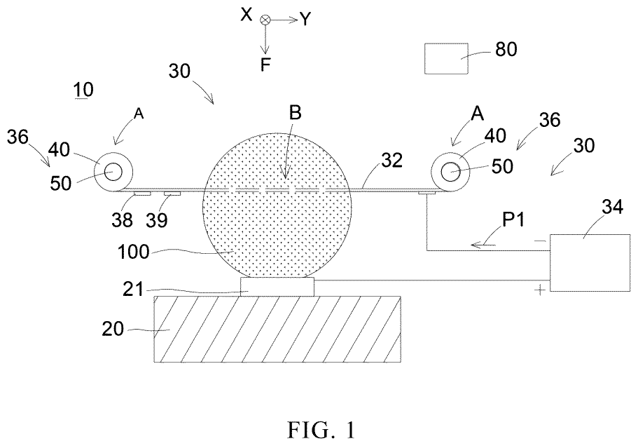

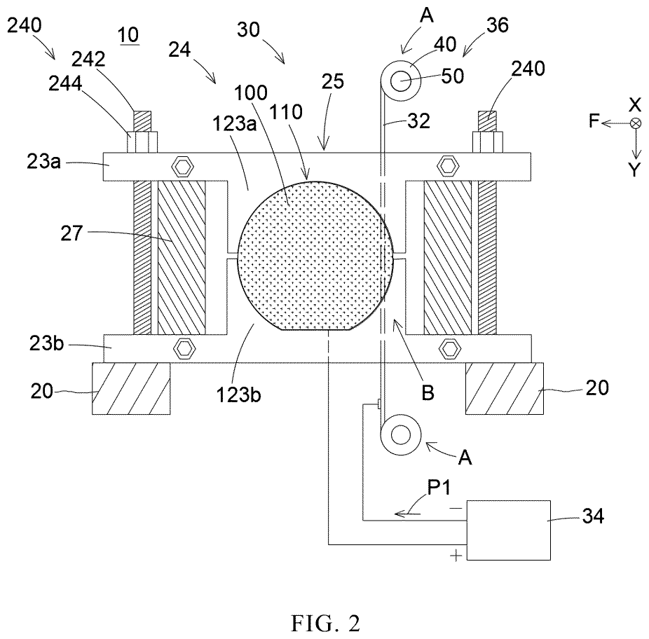

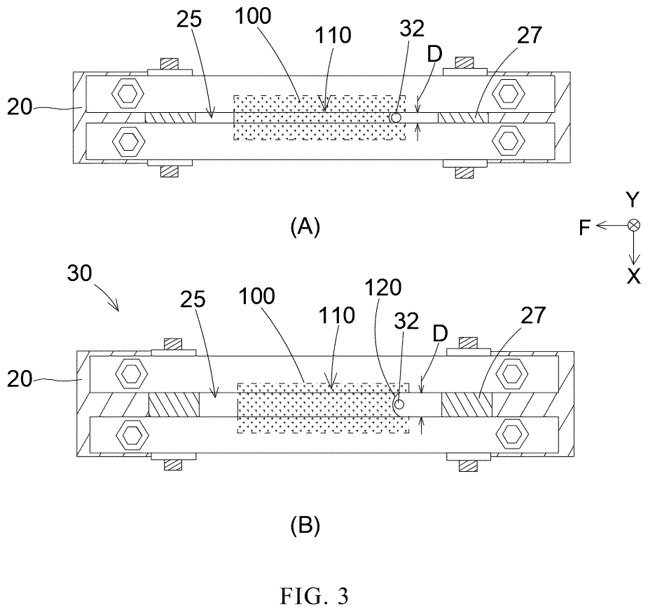

FIG. 1 is a front view of an electrical discharge machining apparatus of the disclosure, which shows that a carrier carries a to-be-machined object through a bearing plate. FIG. 2 is a front view of the electrical discharge machining apparatus of the disclosure, which shows that the carrier carries the to-be-machined object through a clamping element. FIG. 3 is a top view of the electrical discharge machining apparatus of the disclosure, which shows that the carrier carries the to-be-machined object through the clamping element. Please refer to FIGS. 1 to 3 at the same time. An electrical discharge machining apparatus 10 of the disclosure comprises at least one carrier 20 and at least one electrical discharge machining unit 30. The carrier 20 is used to carry at least one to-be-machined object 100. The carrier 20 of the disclosure is a fixed-position carrier, or a movable or rotatable motional carrier, wherein the carrier 20 of the disclosure could optionally have a bearing plate 21 (as shown in FIG. 1), or could optionally omit the bearing plate 21 (as shown in FIGS. 2 and 3). The above-mentioned forms of the carrier 20 are only examples and are not intended to limit the disclosure.

The to-be-machined object 100 could be any conductor or semiconductor material, such as an ingot or a wafer, or even any material suitable for electrical discharge machining, and its shape could be, for example, a cylindrical block or a sheet. The to-be-machined object 100 is defined with at least one machining target area 110, such as the single machining target area 110 or the machining target areas 110. Taking semiconductor material as an example, the to-be-machined object 100 is selected from a semiconductor material of a group consisting of silicon, gallium arsenide, indium phosphide, gallium nitride and silicon carbide. Taking the machining target areas 110 as an example, the machining target areas 110 are optionally located at any suitable positions for machining in the to-be-machined object 100. A spacing between the machining target areas 110 correspondingly defines (for example, the same as) cutting thickness, thinning thickness or cutting spacing of the to-be-machined object 100, numerical values are adjusted according to actual process requirements, and are therefore not limited to being equal or unequal to one another.

Please continue to refer to FIGS. 1 to 3. The electrical discharge machining unit 30 comprises at least one electrical discharge electrode 32 and at least one power supply unit 34. The electrical discharge electrode 32 of the electrical discharge machining unit 30 extends along a second direction Y, so that an electrical discharge section B of the electrical discharge electrode 32 is parallel to the second direction Y, wherein the second direction Y is perpendicular to a first direction X and a machining feed direction F respectively. The electrical discharge section B of the electrical discharge electrode 32 and the machining target area 110 of the to-be-machined object 100 move relative to each other in a reciprocating or cyclical manner (for example, relative displacement occurs along the second direction Y shown in FIGS. 1 to 3), so as to perform the electrical discharge machining procedure on the machining target area 110 of the to-be-machined object 100 on the carrier 20 with the electrical discharge electrode 32 along the machining feed direction F. The power supply unit 34 of the electrical discharge machining unit 30 provides a power source P1 of electrical discharge energy to the electrical discharge electrode 32 and the to-be-machined object 100 during the electrical discharge machining procedure, so as to apply an electrical discharge energy to the machining target area 110 of the to-be-machined object 100 through the electrical discharge electrode 32 located in the electrical discharge section B. Wherein the power supply unit 34 could be a set of power output or a plurality of sets of power output for supplying the power source P1. The power supply unit 34 could also be electrically connected to the electrical discharge electrode 32 in series or parallel. As long as the electrical discharge energy could be applied to the machining target area 110 of the to-be-machined object 100 through the electrical discharge electrode 32, it is applicable to the disclosure. In addition, in the disclosure, the power supply unit 34 of the electrical discharge machining unit 30 could be, for example, integrated (one-piece) or separated (detachable) and configured on the electrical discharge machining apparatus 10 to supply the power source P to the to-be-machined object 100. For example, configurations of the carrier 20 (and/or, together with a clamping element 24 thereon) and the power supply unit 34 could be, for example, an integrated (one-piece) design or a separated (detachable) design, wherein the carrier 20 could also optionally have the bearing plate 21. In other words, when the carrier 20 and the clamping element 24 thereon carry and clamp the to-be-machined object 100, the power source P could be directly supplied to the to-be-machined object 100 through the power supply unit 34 configured in an integrated (one-piece) design with the carrier 20 (and/or, together with the clamping element 24 thereon). Alternatively, the to-be-machined object 100 is first carried and clamped, and then the power source P1 is supplied to the to-be-machined object 100 through the power supply unit 34 in a separated (detachable) configuration.

The power supply unit 34 of the electrical discharge machining unit 30 provides an electrical discharge energy to the electrical discharge electrode 32 with an electrical discharge frequency, so that the electrical discharge machining unit 30 is capable of performing the electrical discharge machining procedure on the machining target area 110 of the to-be-machined object 100 on the carrier 20 through the electrical discharge electrode 32 with at least one machining parameter along the machining feed direction F, such as performing the electrical discharge machining procedure of cutting, thinning and/or electrical discharge grinding (EDG) on the machining target area 110 of the to-be-machined object 100. The disclosure is not limited to the carrier 20 driving the to-be-machined object 100 to move toward the electrical discharge electrode 32 of the electrical discharge machining unit 30 or the electrical discharge machining unit 30 driving the electrical discharge electrode 32 to move toward the to-be-machined object 100, as long as the electrical discharge electrode 32 of the electrical discharge machining (EDM) unit 30 and the to-be-machined object 100 on the carrier 20 could move relative to each other along the machining feed direction F, it could be applied to the disclosure. Wherein the electrical discharge machining unit 30 of the disclosure has a processing control component (such as a processor) (not shown in the figures), thereby driving the carrier 20 to move or driving the electrical discharge electrode 32 to move toward the to-be-machined object 100, for example, through a servo mechanism (such as stepper motor) (not shown in the figures). Since the electrical discharge machining unit 30 having the processing control component and driving the carrier 20 or the electrical discharge electrode 32 through the servo mechanism are prior art, and a person having ordinary skill in art to which the disclosure pertains should be able to understand how the electrical discharge machining unit 30 is equipped with the processing control component and operates with the servo mechanism based on the disclosure of the disclosure, so no further description is given here.

During the electrical discharge process of the electrical discharge machining procedure, when machining conditions such as a structure of the electrical discharge electrode 32 or a material removal rate of the to-be-machined object 100 changes, for example, before the electrical discharge electrode 32 is disconnected or when a material removal rate becomes smaller, the electrical discharge frequency or the electrical discharge energy (such as electrical discharge frequency or electrical discharge energy per unit time) during the electrical discharge process of the electrical discharge machining procedure will change. The principle is that before the electrical discharge electrode 32 is disconnected or when a material removal rate becomes smaller (for example, when a material of a current cutting position of the to-be-machined object 100 is relatively hard or an electrical conductivity is low), a normal electrical discharge frequency will decrease and an arcing electrical discharge frequency will increase. The above-mentioned change in the electrical discharge frequency or the electrical discharge energy is, for example, a variation in the electrical discharge frequency or the electrical discharge energy exceeding a predetermined threshold value, or the change in the electrical discharge frequency or the electrical discharge energy shows a trend, such as getting lower and lower, getting higher and higher, steep rise or steep fall, or changes such as a ratio of normal electrical discharge to arcing electrical discharge exceeding a predetermined threshold value.

In detail, the disclosure is based on a changing status of the electrical discharge frequency or the electrical discharge energy (such as electrical discharge frequency or electrical discharge energy per unit time) during the electrical discharge process of the electrical discharge machining procedure, for example, measuring or calculating whether a variation of the electrical discharge frequency or the electrical discharge energy exceeds a predetermined threshold value, if it exceeds, it means that a machining status (such as cutting speed, material removal rate, electrical discharge electrode integrity or surface roughness) of the electrical discharge machining procedure begins to change. Since a machining parameter of the electrical discharge machining procedure and intrinsic and extrinsic characteristics of the to-be-machined object 100 will affect a variation of the electrical discharge frequency or the electrical discharge energy, the disclosure could adjust an actual output energy value (such as actual output energy value per unit time) corresponding to a machining parameter in real time through various adjustment schemes in order to maintain the electrical discharge machining procedure in a predetermined target machining status (that is, avoid continuous changes in a machining status), such as maintaining predetermined material removal rate (MRR), maintaining no disconnection, maintaining predetermined surface roughness, maintaining predetermined disconnection frequency or other statuses. Since the disclosure could measure or calculate the electrical discharge frequency or the electrical discharge energy through the conventional electrical discharge machining technologies, and a person having ordinary skill in art to which the disclosure pertains should understand how to use the existing electrical discharge machining technologies to measure or calculate to obtain a changing status of the electrical discharge frequency or the electrical discharge energy based on the disclosure of the disclosure, so theoretical basis and measurement and calculation methods of measuring or calculating the electrical discharge frequency or the electrical discharge energy will not be described in detail here.

In a first adjustment scheme, the electrical discharge machining unit 30 of the disclosure adjusts a machining parameter such as the electrical discharge frequency and/or the electrical discharge energy provided by the power supply unit 34, thereby correspondingly adjusting an actual output energy value corresponding to the machining parameter in real time during performing the electrical discharge machining procedure in order to maintain the electrical discharge machining procedure in a predetermined target machining status. Wherein the disclosure could adjust the electrical discharge energy by adjusting a voltage, for example. In a second adjustment scheme, the electrical discharge machining unit 30 of the disclosure adjusts an actual output energy value in real time by adjusting other machining parameters other than the electrical discharge frequency and/or the electrical discharge energy, such as adjusting numerical values of other machining parameters. For example, a first machining parameter value is adjusted to a second machining parameter value, thereby adjusting an actual output energy value corresponding to the first machining parameter value to an actual output energy value corresponding to the second machining parameter value. A third adjustment scheme combines the first adjustment scheme and the second adjustment scheme, which means simultaneously adjusting the electrical discharge frequency and/or the electrical discharge energy and adjusting the first machining parameter value of another machining parameter to the second machining parameter value. In this way, an actual output energy value could be adjusted in real time correspondingly. Types of machining parameters in the disclosure include one of or more than one of orientation parameter, electrical discharge parameter, debris removal parameter, movement and tension parameters and vibration parameter. The orientation parameter is, for example, machining directions of the electrical discharge electrode 32 relative to the to-be-machined object 100. The electrical discharge parameter includes, for example, electrical discharge frequency and electrical discharge energy, and could also include, for example, one of or more than one of peak current (maximum current passing between two poles of the electrical discharge electrode 32 during electrical discharge), voltage when the to-be-machined object 100 is away from the electrical discharge electrode 32, electrical discharge pulse duration, electrical discharge pulse rest time, and gap voltage corresponding to electrical discharge gap. The debris removal parameter includes a flow rate of a debris removal liquid provided on the electrical discharge electrode 32. The debris removal liquid is, for example, water, preferably deionized water, and the debris removal liquid is, for example, provided between two end points of the electrical discharge electrode 32. The movement and tension parameters include one of or more than one of movement speed of the electrical discharge electrode 32, tension of the electrical discharge electrode 32, and vibration of the electrical discharge electrode 32. In addition, a machining parameter of the disclosure could also optionally include a feedback adjustment speed of one of or more than one of the above machining parameters. For example, the disclosure could perform data analysis on machining statuses of the different to-be-machined objects 100 correspondingly obtained in the electrical discharge machining procedure according to a plurality of machining parameters, thereby obtaining machining parameters that affect machining statuses of the different to-be-machined objects 100. The different to-be-machined objects 100 comprise, for example, differences in intrinsic characteristics (such as doping concentration, resistivity, defects or blemishes) or differences in extrinsic characteristics (such as thickness), such as different doping concentrations or resistivities, or different thicknesses. In addition, the disclosure could also optionally create a corresponding relational table of corresponding relations between the intrinsic and extrinsic characteristics, values and types of machining parameters, machining statuses, electrical discharge frequencies, electrical discharge energy and actual output energy values of the to-be-machined objects 100. Thereby, the disclosure could select values or types of optimal machining parameters from the above-mentioned corresponding relational table for adjustment according to a required target result (i.e., target machining status). In short, the disclosure could make adjustment by selecting at least one of the values or types of the machining parameters from the above-mentioned corresponding relational table in order to maintain the electrical discharge machining procedure in the target machining status. The above-mentioned machining statuses are, for example, selected from a group consisting of cutting speed, material removal rate, material loss rate and surface roughness of the to-be-machined object 100 and disconnection frequency of the electrical discharge electrode 32. In addition, the disclosure could also optionally perform a non-destructive detection step on the to-be-machined object 100, thereby obtaining the above intrinsic characteristics. Taking the above intrinsic characteristics as blemishes or defects as an example, the disclosure could optionally use a non-destructive detection device 80, such as ultrasonic detection device, X-ray detection device or infrared detection device to perform a non-destructive detection step on the to-be-machined object 100 before, during or after performing the electrical discharge machining procedure (such as cutting) on the to-be-machined object 100, the disclosure could detect an internal status of the to-be-machined object 100 (such as an ingot or a wafer), such as location or degree of defects or blemishes, before, during or after cutting, so that corresponding adjustments could be made. The above detection results could even be fed back to the electrical discharge machining apparatus 10 to obtain optimal machining parameters by combining the non-destructive detection with one of or more than one of the above machining parameters.

Please continue to refer to FIGS. 1 to 3. In the first embodiment, two sides A of the electrical discharge electrode 32 of the electrical discharge machining unit 30 of the disclosure butt against two jigs 36. The jig 36 is, for example, composed of at least two bearing members 40 and at least two holding members 50 that are respectively assembled correspondingly, but is not limited thereto. The two sides A of the electrical discharge electrode 32 movably or fixedly butt against the two bearing members 40 respectively, so that the electrical discharge section B of the electrical discharge electrode 32 is in a suspended status, thereby the machining target area 110 of the to-be-machined object 100 could be performed with the electrical discharge machining procedure through the electrical discharge section B. The holding members 50 are detachably or fixedly assembled with the bearing members 40. The two jigs 36 are connected to a motion mechanism (such as stepper motor) (not shown in the figures) through the holding members 50, wherein the motion mechanism is capable of causing the two jigs 36 to rotate or move, wherein the electrical discharge machining unit 30, for example, could also drive the motion mechanism to operate in conjunction with above-mentioned servo mechanism through the processing control component, so as to jointly make the electrical discharge electrode 32 to move in a reciprocating or cyclical manner along a tension direction (Y-axis), and move forward and backward along the machining feed direction (F axis). The electrical discharge electrode 32 of the electrical discharge machining unit 30 of the disclosure could, for example, have a fixed tension value, or could have an adjustable tension value, for example. By using the motion mechanism (not shown in the figures) to cause the two jigs 36 to generate relative displacement, for example, moving in directions toward or away from each other, thereby adjusting a tension value of the electrical discharge electrode 32. Wherein the electrical discharge machining unit 30 of the disclosure could optionally have a tension measuring unit 38 for measuring a tension value of the electrical discharge electrode 32. The tension measuring unit 38 could be, for example, a conventional and commercialized tensiometer, and therefore will not be described again here. In addition, the disclosure could optionally comprise a vibration measuring unit 39 for measuring a vibration value of the electrical discharge electrode 32.

The electrical discharge electrode 32 has an outer shape, for example, linear shape, sheet shape, or other various shapes. A number of the electrical discharge electrode 32 could be, for example, one or a plurality, and a number of the to-be-machined object 100 could also be, for example, one or a plurality. Among the electrical discharge electrodes 32, each of the electrical discharge electrodes 32 could optionally have an independently controlled machining feed speed, and a retracting and releasing wire set (e.g., the jig 36) of each of the electrical discharge electrodes 32 could be independent or shared. Therefore, in the disclosure, the electrical discharge electrode 32 or the electrical discharge electrodes 32 could optionally perform the electrical discharge machining procedure on the same to-be-machined object 100 or the different to-be-machined objects 100 respectively, that is, performing the electrical discharge machining procedure on the machining target area 110 or the machining target areas 110 on the same to-be-machined object 100 or the different to-be-machined objects 100. When the electrical discharge electrode 32 or the electrical discharge electrodes 32 performs/perform the electrical discharge machining procedure on the same to-be-machined object 100 or the different to-be-machined objects 100 respectively, the electrical discharge machining procedure will correspondingly have a plurality of machining feed speeds. Therefore, the electrical discharge machining unit 30 of the disclosure could optionally use, for example, a slowest one among the machining feed speeds as a common machining feed speed. Thereby, the electrical discharge electrodes 32 could have a common machining feed speed. In other words, when the electrical discharge electrodes 32 machine the same to-be-machined object 100, an overall machining feed speed is determined by the slowest one. Similarly, since the to-be-machined object 100 is carried on the carrier 20, if the carrier 20 is a movable carrier, the carrier 20 uses the above common machining feed speed as a moving speed. However, the above is only an example and is not intended to limit the disclosure. When performing the electrical discharge machining procedure of the disclosure, the electrical discharge electrodes 32 could optionally have independently controlled machining feed speeds, thereby the electrical discharge electrodes 32 could have their own machining feed speeds.

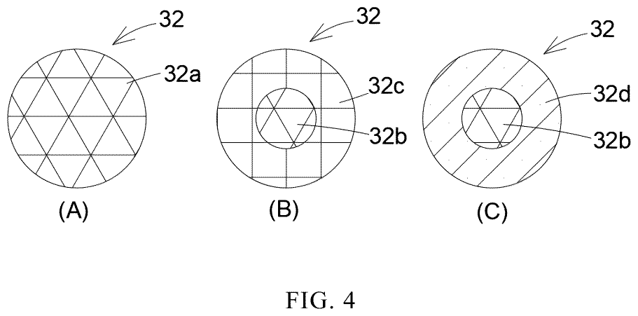

As shown in FIG. 4(A), the electrical discharge electrode 32 of the disclosure could be composed of a conductive material layer 32a, wherein a material of the conductive material layer 32a is, for example, selected from a group consisting of copper, brass, molybdenum, tungsten, graphite, steel, aluminum, zinc, nickel and diamond. Alternatively, as shown in FIG. 4(B), an interior of the electrical discharge electrode 32 is, for example, a metal layer 32b, and has a diamond layer 32c covering an outer periphery of the metal layer 32b, thereby an effect of grinding and polishing could be achieved simultaneously during an electrical discharge process (i.e., electrical discharging while grinding and polishing). Alternatively, as shown in FIG. 4(C), an interior of the electrical discharge electrode 32 is, for example, the metal layer 32b, and has a dielectric material layer 32d covering an outer periphery of the metal layer 32b. Therefore, the electrical discharge electrode 32 could serve as a capacitive sensing element during the electrical discharge process, providing a sensing capacitance value as an electrical discharge feedback signal by detecting a capacitance change during the electrical discharge process in real time. A material of the dielectric material layer 32d is, for example, ceramics or Teflon, but is not limited to the above examples. A material of metal layer 32b is, for example, selected from a group consisting of copper, brass, molybdenum, tungsten, steel, aluminum, zinc and nickel. A thickness of the electrical discharge electrode 32 is less than about 300 μm, and preferably ranges from about 30 μm to about 300 μm.

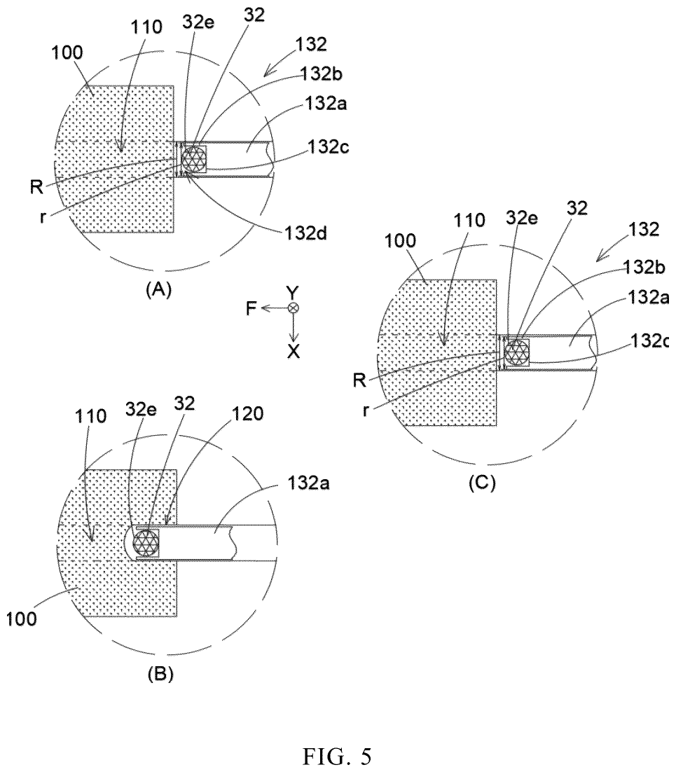

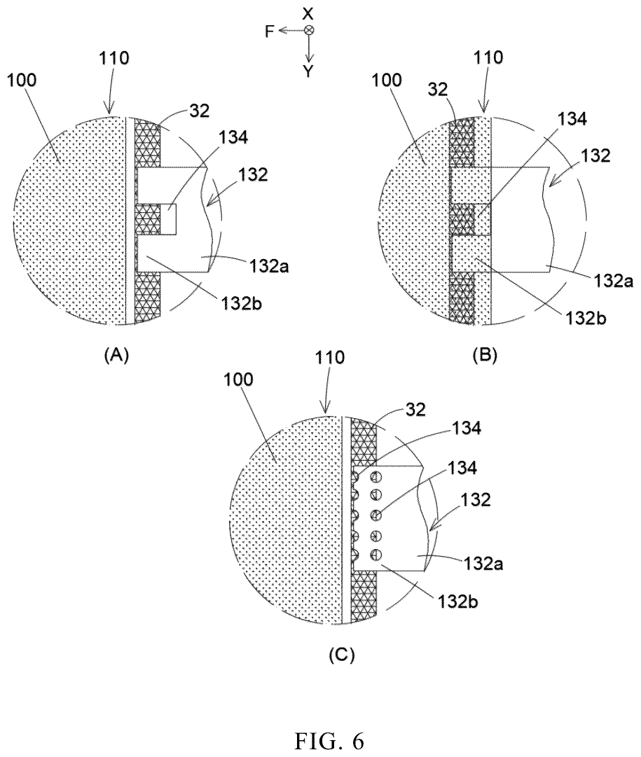

In addition, as shown in FIGS. 5 to 6, FIGS. 5(A), 5(C), 6(A) and 6(C) represent that the electrical discharge electrode 32 has not yet formed a machining groove 120 on the to-be-machined object 100, and FIG. 5(B) and FIG. 6(B) represent that the electrical discharge electrode 32 has formed the machining groove 120 on the to-be-machined object 100. The electrical discharge machining unit 30 of the disclosure optionally comprises an insulating sleeve 132, and the insulating sleeve 132 is composed of electrically insulating material. The insulating sleeve 132 of the disclosure is sleeved on an outer side of the electrical discharge electrode 32 along a tension direction (i.e., Y-axis direction) of the electrical discharge electrode 32. The insulating sleeve 132 is not limited to a fixed or movable type to be sleeved on an outer side of the electrical discharge electrode 32. Therefore, relative positions of the insulating sleeve 132 and the electrical discharge electrode 32 in a tension direction could be fixed or relatively moved as required. The insulating sleeve 132 exposes at least one surface of the electrical discharge electrode 32 in the machining feed direction F of the electrical discharge machining procedure, so that the above surface serves as an electrical discharge surface 32e of the electrical discharge electrode 32 during the electrical discharge process of the electrical discharge machining procedure. Wherein the insulating sleeve 132 partially covers the electrical discharge electrode 32, but preferably only a surface of the electrical discharge electrode 32 in the machining feed direction F of the electrical discharge machining procedure is exposed. The disclosure uses the insulating sleeve 132 to cover a periphery (that is, a surface outside of the machining feed direction F) of the electrical discharge electrode 32. A purpose is to reduce kerf loss (or material machining loss), which could effectively improve the problem that the traditional electrical discharge electrode 32 and the to-be-machined object 100 are prone to unexpected damage. In the disclosure, an electrical discharge area R formed by the electrical discharge surface 32e exposed by the electrical discharge electrode 32 during the electrical discharge process is substantially greater than a cross-section r of the insulating sleeve 132, thereby both the electrical discharge electrode 32 and the insulating sleeve 132 could enter into the machining groove 120, that is, the electrical discharge area R only needs to be slightly greater than the cross-section r of the insulating sleeve 132 to be applicable to the disclosure. In other words, the disclosure could improve a precision of electrical discharge machining and avoid the problem that the conventional electrical discharge electrode 32 and the to-be-machined object 100 are prone to unexpected damage. For example, the insulating sleeve 132 comprises a bottom plate 132a and two side walls 132b. The insulating sleeve 132 is, for example, provided on the jig 36 or the carrier 20 (as shown in FIG. 2) through the bottom plate 132a, or on a surrounding environment of the to-be-machined object 100. The two side walls 132b are located at two ends of the bottom plate 132a to form a trough 132c. Wherein two ends of the trough 132c are open ends, an interior of the trough 132c forms a chamber for accommodating the electrical discharge electrode 32, the trough 132c has an opening 132d communicated to the chamber, and the insulating sleeve 132 exposes the electrical discharge surface 32e of the electrical discharge electrode 32 located in the chamber through the opening 132d. In one mode, relative positions of the insulating sleeve 132 and the electrical discharge electrode 32 in the machining feed direction F of the electrical discharge machining procedure are, for example, fixed, and relative positions of the insulating sleeve 132 and the electrical discharge electrode 32 in a tension direction of the electrical discharge electrode 32 are, for example, movable. In short, the electrical discharge electrode 32 is movably sleeved in the insulating sleeve 132, both the insulating sleeve 132 and the electrical discharge electrode 32 move along the machining feed direction F (e.g., longitudinal displacement), but only the electrical discharge electrode 32 displaces leftward and rightward, while the insulating sleeve 132 does not displace leftward and rightward. However, the disclosure is not limited thereto.

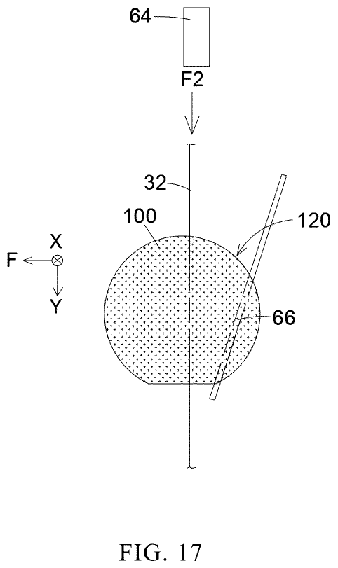

In another mode, relative positions of the insulating sleeve 132 and the electrical discharge electrode 32 in the machining feed direction F of the electrical discharge machining procedure and a tension direction of the electrical discharge electrode 32 are fixed, for example. In addition, although the insulating sleeve 132 preferably only exposes a surface of the electrical discharge electrode 32 in the machining feed direction F, the disclosure is not limited thereto. For example, the insulating sleeve 132 of the disclosure optionally has one notch 134 or a plurality of notches 134 (as shown in FIG. 6(A), FIG. 6(B), and FIG. 6(C)), such as a plurality of micro holes located in the side walls 132b, and the trough 132c could be communicated externally through the notches 134 to provide a function of debris removal (e.g., water drainage or scraps removal) during the electrical discharge machining procedure. The notches 134 are disposed to remove debris or water flow (i.e., an external force F2 generated by a debris removal unit 64 depicted in FIG. 17) and keep the debris or water flow away from the electrical discharge electrode 32, and therefore are not limited to a specific orientation, location, size or quantity, as long as the insulating sleeve 132 could protect the electrical discharge electrode 32 and provide a debris removal function at the same time, any orientation, location, size or quantity is applicable to the disclosure.

Please refer to FIGS. 1 to 3 and 7 again. In addition to performing dry electrical discharge machining on the to-be-machined object 100 in a dry machining environment such as a gaseous fluid environment or a vacuum environment, the electrical discharge machining unit 30 of the disclosure could also perform wet electrical discharge machining on the to-be-machined object 100 in a wet machining environment by immersing the to-be-machined object 100 in a liquid in a tank 41 or spraying the liquid on the to-be-machined object 100. The liquid is, for example, an aqueous solution or an electrolyte. In detail, the electrical discharge machining unit 30 of the disclosure could perform the electrical discharge machining procedure on the machining target area 110 of the to-be-machined object 100 in a liquid such as an aqueous solution or an electrolyte, for example. Taking the liquid as an electrolyte as an example, the electrical discharge electrode 32 is electrically connected to a cathode of the power supply unit 34 (as shown in FIG. 1), and the to-be-machined object 100 is electrically connected to an anode of the power supply unit 34. Therefore, during the electrical discharge machining procedure, electrolysis reaction could occur simultaneously. Through the cathodic protection phenomenon of electrolysis reaction, the disclosure could prevent metal components of the electrical discharge electrode 32 from being dissolved in the electrolyte during the electrical discharge machining procedure, so it could reduce fracture phenomenon of the electrical discharge electrode 32. The electrolysis reaction could cause the water in the electrolyte to generate hydrogen on the machining target area 110 of the to-be-machined object 100. Generation of hydrogen bubbles helps to remove debris in the machining groove 120 and improves a cleaning effect of the to-be-machined object 100. Moreover, based on the principle that the same electrical properties repel each other, negatively charged debris could be prevented from sticking on the electrical discharge electrode 32 or in the machining groove 120.

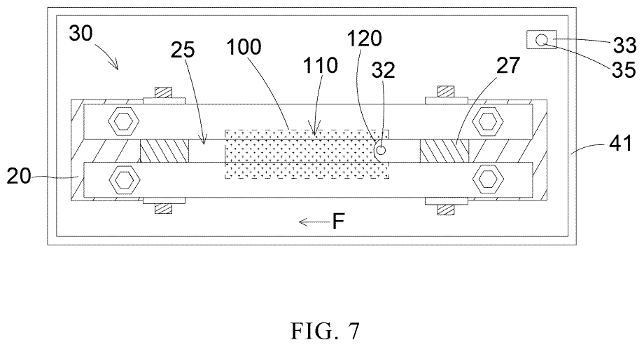

A temperature range in which the electrical discharge machining unit 30 of the disclosure could perform the electrical discharge machining procedure is, for example, less than or equal to about 100 degrees Celsius. That is to say, a preset temperature in which the electrical discharge machining unit 30 of the disclosure could perform the electrical discharge machining procedure is any temperature value of less than or equal to about 100 degrees Celsius. For example, a relatively low temperature range applicable to the disclosure is, for example, from about 0 degrees Celsius to about 100 degrees Celsius, and for example, from about 22 degrees Celsius to about 100 degrees Celsius. The above-mentioned preset temperature is any temperature value in the temperature range, such as room temperature. Since a maximum machining environment temperature required for performing the electrical discharge machining procedure of the disclosure does not exceed 100 degrees Celsius, the disclosure could even use a machining environment such as the tank 41 with an aqueous solution to perform the electrical discharge machining procedure, without having to use the traditional high-temperature oil solutions, and therefore could significantly save energy consumption and improve convenience. In addition, the electrical discharge machining unit 30 of the disclosure further optionally comprises a temperature control unit 33 for providing a heat source and/or a cold source when performing the electrical discharge machining procedure. Wherein the heat source and/or the cold source could, for example, directly adjust a temperature of the to-be-machined object 100, or indirectly adjust a temperature of the to-be-machined object 100 through various components of the electrical discharge machining apparatus 10, such as the clamping element 24 (as shown in FIG. 2), a guide structure 66 (as shown in FIG. 17), the carrier 20 (as shown in FIG. 2), the electrical discharge electrode 32 (as shown in FIG. 2), the bearing plate (as shown in FIG. 1), the insulating sleeve 132 (as shown in FIG. 5) and/or the liquid in the tank 41 (as shown in FIG. 7), thereby the electrical discharge machining procedure could be performed on the to-be-machined object 100 in the above-mentioned temperature range or preset temperature. The temperature control unit 33 could, for example, comprise a heat source such as infrared ray, microwave or electric heater that could be used as a heating element. The temperature control unit 33 could also comprise a cold source such as a refrigerator that could be used as a cooling element. Wherein the cold source could optionally be used in conjunction with an antifreeze agent to prevent a machining environment (such as the above-mentioned aqueous solution) of the electrical discharge machining unit 30 from freezing. In addition, the temperature control unit 33 has, for example, a temperature sensor 35. The temperature control unit 33 could use the temperature sensor 35 to detect whether a machining environment of the to-be-machined object 100 reaches a target temperature (such as the above-mentioned temperature range or preset temperature) to maintain the machining environment at the target temperature. In addition, in order to further improve a machining efficiency, the disclosure could further add ozone (such as gaseous state or liquid state) or bubbles (such as microbubbles) to a machining environment (such as the above-mentioned aqueous solution) of the electrical discharge machining unit 30, through oxidation, softening or bursting (such as implosion), it could not only increase an electrical discharge machining speed and improve an electrical discharge machining quality, but also help to remove carbides or residue generated on a surface of the electrical discharge electrode 32, thereby reducing the erosion of the electrical discharge electrode 32.

In addition, as shown in FIGS. 2 and 3, the carrier 20 of the electrical discharge machining apparatus 10 of the disclosure optionally comprises the at least one clamping element 24, and the clamping element 24 radially (as shown in FIGS. 2 and 3) or axially applies a force to fix the to-be-machined object 100. The clamping element 24 of the disclosure could, for example, comprise a first butting element 23a and a second butting element 23b, wherein the first butting element 23a and the second butting element 23b respectively have a first butting portion 123a and a second butting portion 123b for respectively butting against two opposite sides of the to-be-machined object 100, for example, two opposite sides in a radial direction. At least one (e.g., both) of the first butting element 23a and the second butting element 23b of the clamping element 24 of the disclosure has one slit 25 or a plurality of slits 25 to form a slit structure. A span D of the slit 25 is, for example, substantially greater than a width of the electrical discharge electrode 32, thereby enabling the electrical discharge electrode 32 to insert into the clamping element 24 through the slit 25. When the clamping element 24 clamps the to-be-machined object 100, the slit 25 correspondingly exposes the machining target area 110 of the to-be-machined object 100, and a position of the slit 25 corresponds to a position of the machining groove 120, for example, the slit 25 and the machining groove 120 are distributed along the machining feed direction F. The disclosure could move the electrical discharge electrode 32 along the slit 25 in order to perform the electrical discharge machining procedure on the machining target area 110 of the to-be-machined object 100 clamped by the clamping element 24, that is, forming the machining groove 120 on the machining target area 110 of the to-be-machined object 100. Outer shapes of the first butting portion 123a and the second butting portion 123b could be similar to each other, the same or different from each other, could be, for example, flat, arcuate, curved or other shapes, and preferably corresponding to an outer shape of the to-be-machined object 100. For example, taking the to-be-machined object 100 as a circular crystal ingot as an example, the first butting element 23a and the second butting element 23b respectively butt against two radial sides of the to-be-machined object 100, and outer shapes of the first butting portion 123a and the second butting portion 123b could be, for example, arc-shape, and could even be optionally partially or completely conformal to a contour of at least a portion of a periphery of the to-be-machined object 100, thereby the to-be-machined object 100 could be clamped more firmly. In addition, a degree (or a degree of conformity to the to-be-machined object 100) to which the clamping element 24 of the disclosure adheres to the to-be-machined object 100, for example, changes correspondingly based on a degree of clamping between the clamping element 24 and the to-be-machined object 100. For example, contours of clamping surfaces (such as surfaces of the first butting portion 123a and the second butting portion 123b) of the clamping element 24 could change correspondingly along with a surface contour of the to-be-machined object 100, Thereby, a degree of conformity between a clamping surface of the clamping element 24 and a peripheral contour of the to-be-machined object 100 is correspondingly adjusted along with a clamping degree. In a feasible application example, an outer layer of the clamping element 24 is a clamping surface, and the outer layer is a deformable structure such as a soft surface layer or a flexible surface layer, or a deformable structure with restoring force. An inner layer of the clamping element 24 is a support member, and the support member is a structure that is not easily deformed. Therefore, before, during and after the clamping element 24 locking the to-be-machined object 100, a degree of the clamping element 24 adhering to the to-be-machined object 100 is different, so a degree of adhesion between a clamping surface of the clamping element 24 and a contour of the to-be-machined object 100 could be changed correspondingly according to a degree of clamping. That is, when the clamping element 24 completely locks the to-be-machined object 100, a degree of adhesion (conformity) between a clamping surface of the clamping element 24 and a contour of the to-be-machined object 100 reaches a highest level.

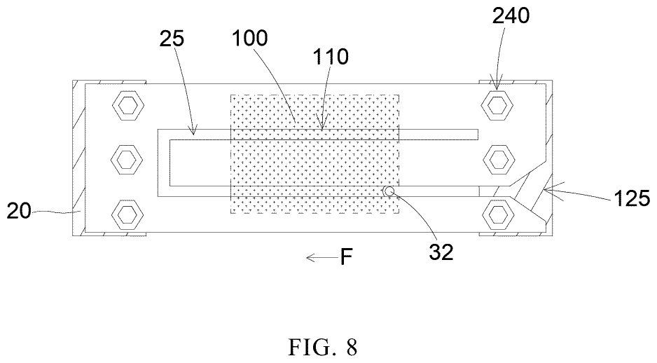

In addition, in the disclosure, a number of the slit 25 of the clamping element 24 could be one or a plurality, wherein the slits 25 could be independent (as shown in FIG. 3), or at least two of the slits 25 could be communicated to each other (as shown in FIG. 8), thereby the electrical discharge electrode 32 could move from one of the slits 25 to the other slit 25 through this communicated design, so as to correspondingly form the machining grooves 120 at different positions without requiring to disassemble a structure of the clamping element 24, and without requiring to reintroduce the electrical discharge electrode 32.

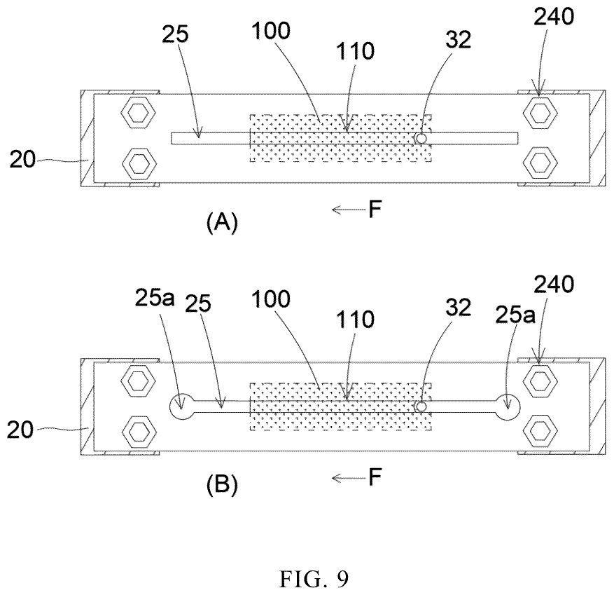

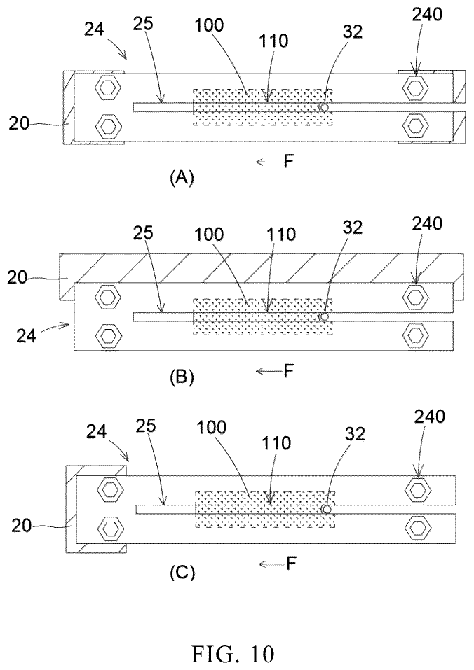

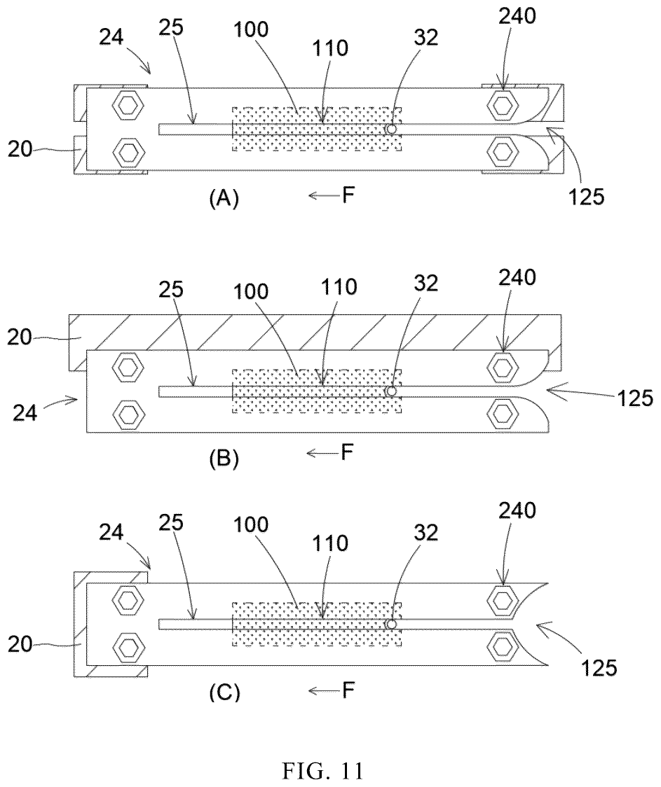

The clamping element 24 of the disclosure has the slit structure that could be used to firmly clamp the to-be-machined object 100, such as clamping upper and lower ends of the to-be-machined object 100 respectively (as shown in FIG. 2), and could also be used for the electrical discharge electrode 32 to pass through the slit 25 of the slit structure to perform the electrical discharge machining procedure on the to-be-machined object 100 along an extending direction of the slit 25 to form the machining groove 120, so that the electrical discharge electrode 32 could be prevented from damaging the clamping element 24. In the disclosure, a shape of the slit 25 is selected from a group consisting of closed type without opening (as shown in FIG. 9(A) and FIG. 9(B)), single-sided opening type (as shown in FIG. 10(A) and FIG. 10(B)) and double-sided opening type (shown in FIG. 3). Wherein taking the single-sided opening type or the double-sided opening type as an example, if the carrier 20 of the disclosure has the corresponding single-sided or double-sided opening (as shown in FIG. 10(A) and FIG. 11(A)), it will be conducive to the electrical discharge electrode 32 inserting into the slit 25, but the disclosure is not limited thereto. It could be that the carrier 20 does not have the corresponding single-sided or double-sided opening, or the clamping element 24 of the disclosure could be located on a side of the carrier 20 (as shown in FIGS. 10(B), 10(C), 11(B) and 11(C)), for example, thereby making it convenient for the electrical discharge electrode 32 to insert into the slit 25. The slit structure of the disclosure is not limited to specific size, material, number of slit openings, or disposed orientation, as long as it could enable the carrier 20 and/or the clamping element 24 to clamp the to-be-machined object 100 during the electrical discharge machining procedure, it belongs to the scope of protection claimed by the disclosure. In other words, a span of the slit 25 of the slit structure and a spacing between the slits 25 are not limited to being the same or different from one another. In addition, the slit 25 of the clamping element 24 of the disclosure is not limited to having equidistant span. The slit 25 could also optionally have non-equidistant span (as shown in FIG. 11(A) and FIG. 11(B), or as shown in FIG. 9(B)), for example, a span at end edges (e.g., threading end) of the slit 25 is greater than a span in a middle of the same slit 25 (e.g., electrical discharge machining end) to form a guide groove 125, and an edge of the guide groove 125 could also be optionally designed to be in a convex arc shape (as shown in FIG. 11(B)) or a concave arc shape (as shown in FIG. 11(C)), thereby facilitating guiding the electrical discharge electrode 32 into the slit 25 of the clamping element 24. In addition, taking the non-equidistant span as an example, the clamping element 24 (slit structure) of the disclosure could optionally have an auxiliary hole 25a communicated to the slit 25, wherein the auxiliary hole 25a is, for example, located on a single side or double sides of the slit 25 (as shown in FIG. 9(B)). Thereby, the disclosure could first insert the electrical discharge electrode 32 into the auxiliary hole 25a, and then move the electrical discharge electrode 32 from the auxiliary hole 25a to the slit 25, so that the electrical discharge electrode 32 could be inserted into the slit 25 of the clamping element 24 more easily. The slit 25 of the clamping element 24 of the disclosure is not limited to having a fixed span, the slit 25 could optionally have an adjustable span. For example, the clamping element 24 of the disclosure could optionally have at least one gasket 27 (as shown in FIG. 3). The gasket 27 is located in the slit 25 of the clamping element 24 and butts against two side walls of the slits 25 respectively, thereby a span of the slit 25 could be adjusted by changing a thickness of the gasket 27 (as shown in FIG. 3(A)). Since a purpose of the gasket 27 is to adjust a span of the slit 25, a length of the gasket 27 is not particularly limited. However, if a length of the gasket 27 extends from the first butting element 23a to reach the second butting element 23b (as shown in FIG. 2), it could additionally provide an efficacy of an overall structural stability for the clamping element 24.

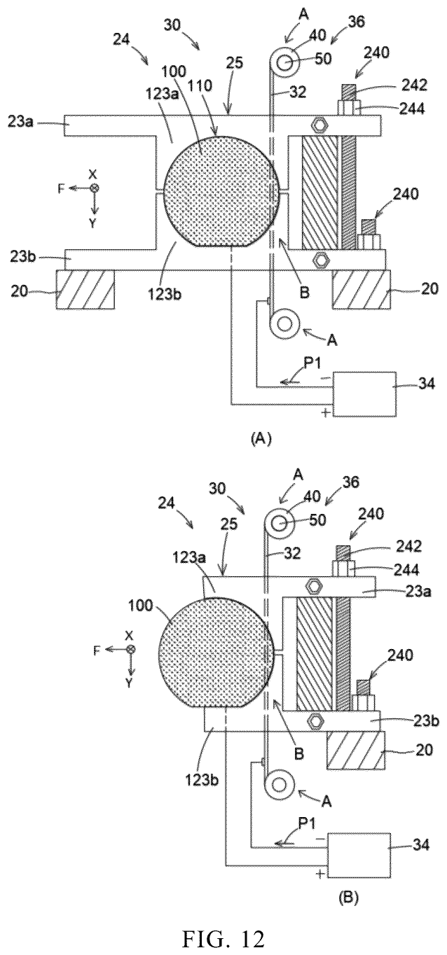

In addition, in the disclosure, the clamping element 24 is not limited to being fixed or detachable on the carrier 20. Taking the detachable design as an example, the first butting element 23a and the second butting element 23b of the clamping element 24 could be detachably connected to each other, for example, through a lock-in structure 240, which could be a single-sided lock-in structure (two modes of the clamping element 24 shown in FIG. 12(A) and FIG. 12(B)) or a double-sided lock-in structure (shown in FIG. 2), and the second butting element 23b below could also be optionally detachably connected to the carrier 20, for example, through the lock-in structure 240 (as shown in FIG. 12). The clamping element 24 of the disclosure could not only detachably clamp the to-be-machined object 100 through the lock-in structure 240, but also adjust a size of a clamping opening of the clamping element 24 correspondingly according to a size of the to-be-machined object 100. Wherein the lock-in structure 240 comprises, for example, but is not limited to, a bolt 242 and a nut 244 (as shown in FIGS. 2 and 12). The lock-in structure 240 of the disclosure could be replaced with any structural design that enables the clamping element 24 to clamp the detachable to-be-machined object 100 according to actual requirements. That is to say, as long as a detachable effect could be achieved, it belongs to the scope of protection claimed by the disclosure.

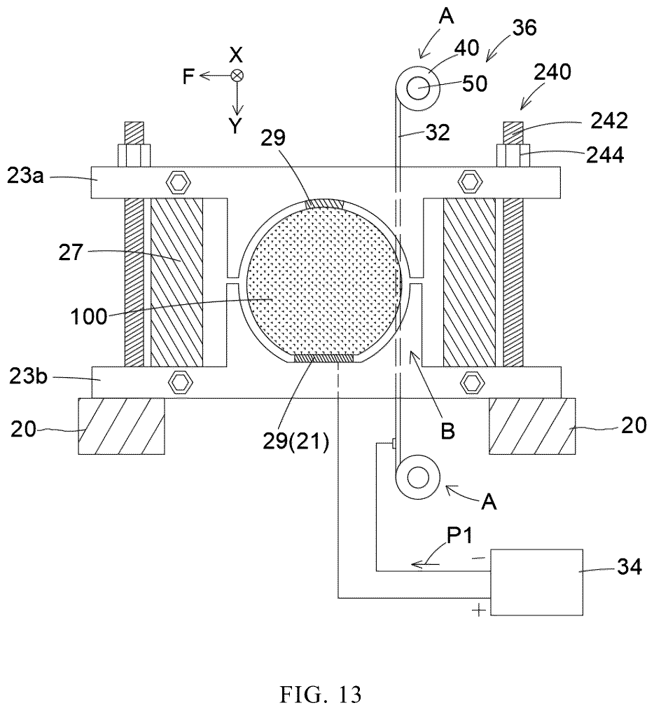

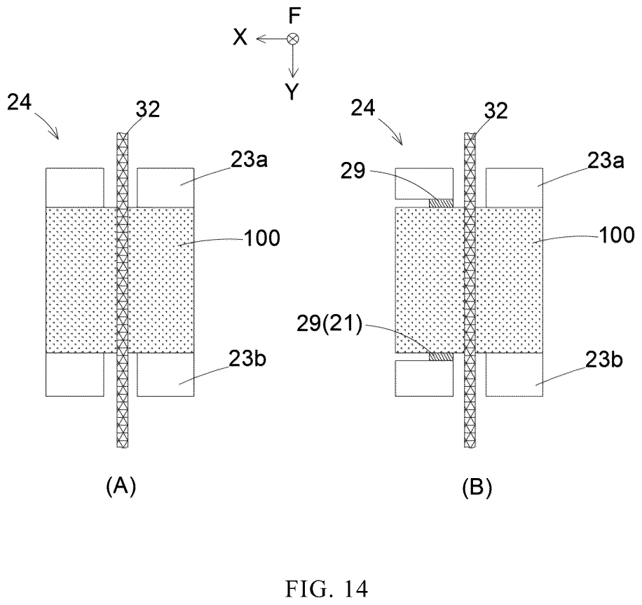

In the disclosure, in addition to using direct contact (as shown in FIG. 2 and FIG. 14(A)) to clamp the to-be-machined object 100, the clamping element 24 could also use indirect contact (as shown in FIG. 13 and FIG. 14(B)) to clamp the to-be-machined object 100. Taking indirect contact as an example, the clamping element 24 is partially connected or adhered to the to-be-machined object 100 through a buffer member 29, wherein a material of the buffer member 29 is, for example, conductor or insulator, and it could be, for example, solid medium, soft medium, or adhesive. For example, the buffer member 29 could be a conductive or non-conductive adhesive layer, or the buffer member 29 could also be a conductive (such as copper foil) or a non-conductive soft pad, thereby providing both support and buffering effects at the same time. In the disclosure, the buffer member 29 could also be optionally fixed on the first butting element 23a and the second butting element 23b of the clamping element 24, or the buffer member 29 could also be optionally fixed on the to-be-machined object 100, or the buffer member 29 could also be optionally detachably positioned between the first butting element 23a of the clamping element 24 and the to-be-machined object 100, and detachably positioned between the second butting element 23b and the to-be-machined object 100. For example, the clamping element 24 uses copper foil as the buffer member 29 to clamp a partial area of the to-be-machined object 100 (e.g., a crystal ingot) through the copper foil (e.g., about 100 μm thick). Therefore, the disclosure could prevent a partial area of the to-be-machined object 100 to be cut (such as wafer) from directly contacting with the clamping element 24, so the wafer cracking phenomenon that often occurs in the traditional ingot cutting technologies could be effectively avoided.

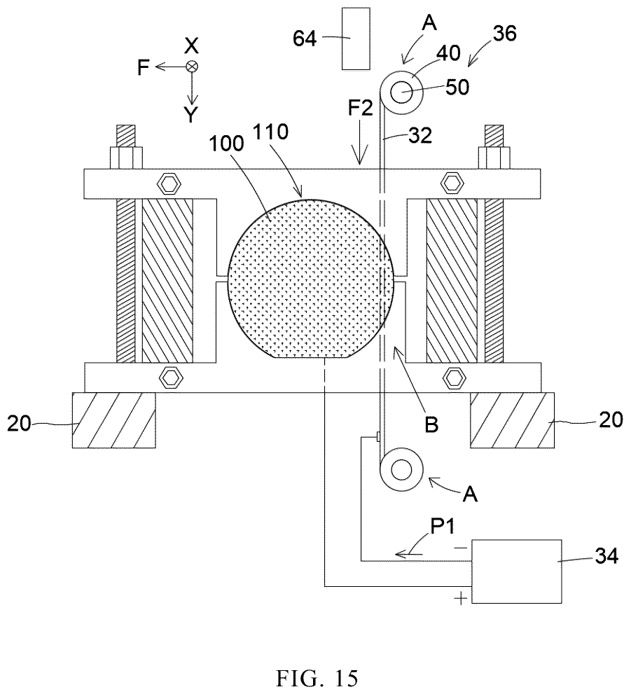

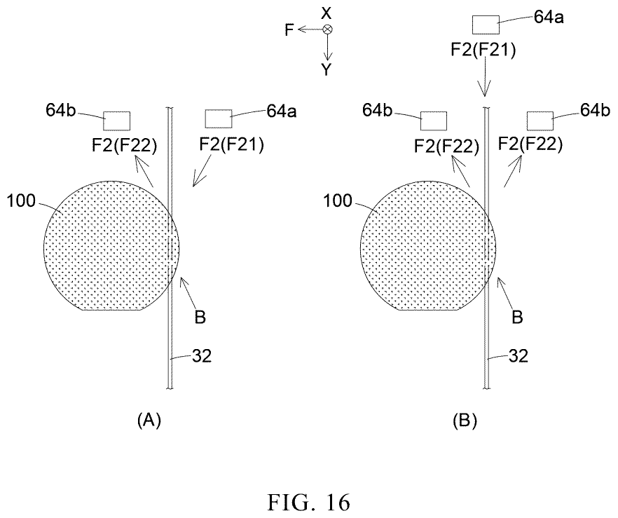

As shown in FIG. 15, since the electrical discharge electrode 32 performs the electrical discharge machining procedure on the to-be-machined object 100, debris will be generated, the electrical discharge machining unit 30 of the disclosure optionally further comprises the debris removal unit 64. When the electrical discharge machining unit 30 performs the electrical discharge machining procedure on the to-be-machined object 100, the debris removal unit 64 is used to provide one external force F2 or more than one external force F2 to remove the debris generated by the electrical discharge energy applied by the electrical discharge electrode 32 to the to-be-machined object 100, applied direction or applied position of the external force F2 generated by the debris removal unit 64 is adjusted to correspond to a shape of the to-be-machined object 100, thereby applied direction or applied position of the external force F2 corresponds to the electrical discharge section B of the electrical discharge electrode 32. Wherein the debris removal unit 64 could be, for example, one or more than one selected from a group consisting of air flow generator, water flow generator, ultrasonic generator, piezoelectric oscillator, suction force generating element and magnetic force generating element. The external force F2 could be, for example, one or more than one selected from a group consisting of air flow, water flow, ultrasonic oscillation, piezoelectric oscillation, suction force and magnetic force. The debris removal unit 64 is not limited to being disposed on the jig 36 or the carrier 20, and could even be disposed around the electrical discharge section B of the electrical discharge electrode 32. As shown in FIGS. 15, 16(A) and 16(B), the debris removal unit 64 is used as a thrust generating device 64a, for example, a water flow generator such as a sprinkler, an air flow generator such as an air jet, and/or a suction generating device 64b (such as a water pump). For example, the debris removal unit 64 could be provided on the jig 36 or the carrier 20, or on a surrounding environment of the to-be-machined object 100, wherein the thrust generating device 64a and the suction generating device 64b are respectively located on two opposite sides of the to-be-machined object 100, and generate the two external forces F2 (thrust force F21 and suction force F22) in two different directions. The thrust generating device 64a and the suction generating device 64b could respectively push and suck out debris generated during the electrical discharge process in the electrical discharge machining procedure, thereby capable of effectively improving an effect of removing debris. Wherein the suction generating device 64b is preferably provided on a moving path of debris pushed by the external force F2. Moreover, the disclosure is not limited to using the thrust generating device 64a and the suction generating device 64b at the same time, that is to say, the disclosure could use the thrust generating device 64a or the suction generating device 64b alone, as long as it is conducive to removing debris, it belongs to the scope of protection claimed by the disclosure.

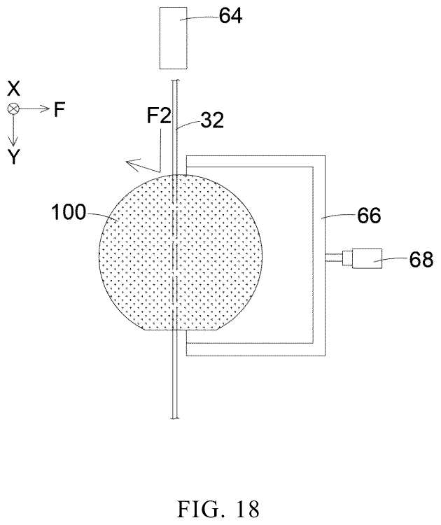

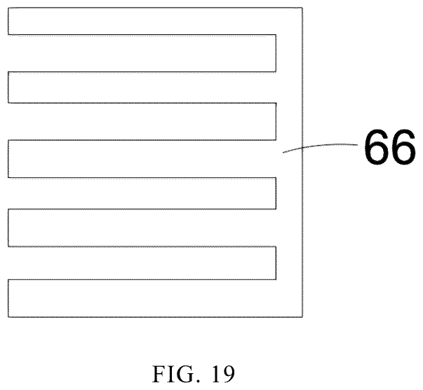

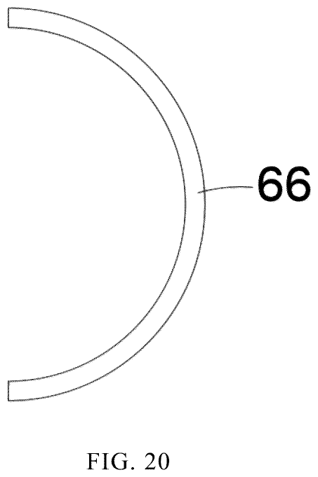

In addition, as shown in FIG. 17, the debris removal unit 64 of the electrical discharge machining unit 30 of the disclosure optionally further comprises the guide structure 66 to guide the external force F2 (such as thrust) generated by the debris removal unit 64 to reach the machining groove 120 on the machining target area 110 of the to-be-machined object 100, thereby producing an auxiliary debris removal effect. The guide structure 66 could, for example, be disposed on the jig 36 or the carrier 20 (as shown in FIG. 2), or on a surrounding environment of the to-be-machined object 100. The guide structure 66 is a baffle, and is, for example, an externally sealed baffle (as shown in FIG. 18) used for covering an area of the machining target area 110 of the to-be-machined object 100 that has not yet been processed by the electrical discharge machining procedure, and moving a position synchronously along with the electrical discharge electrode 32. The guide structure 66 is, for example, an interdigitated structure (as shown in FIGS. 18 and 19), which has one interdigitated baffle or a plurality of interdigitated baffles corresponding to the machining groove 120 on the machining target area 110 of the to-be-machined object 100 respectively. Wherein a cross-sectional shape of the interdigitated structure could be, for example, straight or curved, and could be, for example, linear shape (as shown in FIG. 17), curved shape such as arc-shape (as shown in FIG. 20), or U-shape (as shown in FIG. 18).

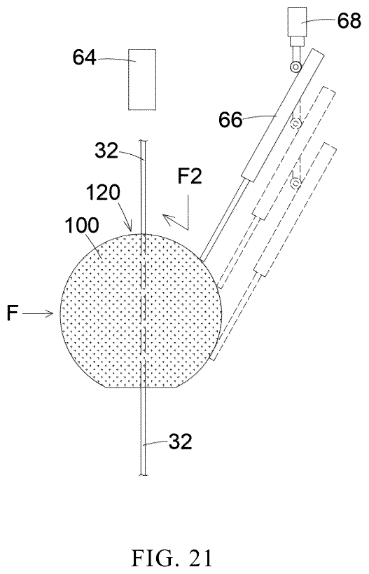

In the disclosure, the guide structure 66 manually (as shown in FIG. 17) or automatically (as shown in FIG. 18) changes position or angle of guiding the external force F2 along with the electrical discharge electrode 32 performing the electrical discharge machining procedure, so as to guide the external force F2 (such as water flow or air flow) provided by the debris removal unit 64 to reach an electrical discharge machining position of the machining groove 120 of the to-be-machined object 100 in the electrical discharge machining procedure currently performed by the electrical discharge electrode 32. In addition, the guide structure 66 of the disclosure could be a filled baffle, which could, for example, move a position along the machining feed direction F. For example, the guide structure 66 of the disclosure moves a position on the machining groove 120 of the machining target area 110 of the to-be-machined object 100 along with the electrical discharge electrode 32 performing the electrical discharge machining procedure, thereby moving in a synchronous filling manner along the machining feed direction F to reach an electrical discharge machining position on the machining groove 120 of the machining target area 110 where the electrical discharge machining procedure has been completed. As shown in FIGS. 18 and 21, in one implementation mode, the guide structure 66 could be, for example, a telescopic baffle. The guide structure 66 is used in conjunction with a telescopic mechanism 68 to have telescopic elasticity, so as to automatically or manually move synchronously along with the electrical discharge electrode 32 to guide the external force F2, and for example, automatically maintain to be adjacent to or butted against the machining groove 120 of the machining target area 110 of the to-be-machined object 100 when the electrical discharge electrode 32 performs the electrical discharge machining procedure, such as adjacent to or butted against an outer side or an inner side of the machining groove 120 of to-be-machined object 100. Wherein the guide structure 66 (telescopic baffle) and the telescopic mechanism 68 could achieve automatic telescopic effect by, for example, springs or telescopic rods (e.g., sleeve-type telescopic rods), as shown in FIG. 21. In addition, the guide structure 66 of the disclosure could also be optionally used in conjunction with a structure shown in FIG. 7, so that the guide structure 66 could optionally adjust position and angle in the slit 25 shown in FIG. 7 to achieve an effect of guiding the external force F2.

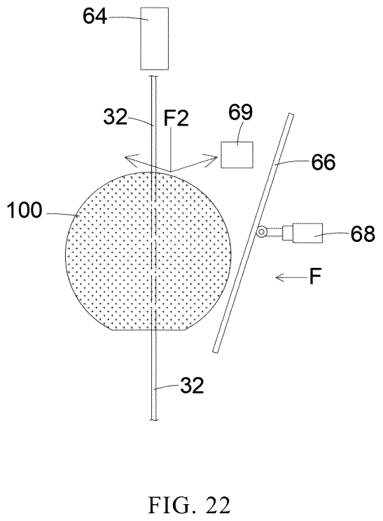

In addition, as shown in FIG. 22, the guide structure 66 of the disclosure could also be optionally used in conjunction with a sensing element 69 for detecting a debris removal status or a guiding status of the external force F2, and could be, for example, a sensing component such as debris amount sensor, air flow sensor, or water flow sensor, used to adjust angle or position of the guide structure 66 based on a sensing result of the sensing element 69, so as to achieve optimal debris removal effect and guiding effect.

Based on above, the electrical discharge machining apparatus and the method of the same of the disclosure have the following advantages and efficacies:

(1) According to a changing status of the electrical discharge frequency or the electrical discharge energy during the electrical discharge process, an actual electrical discharge energy value of the electrical discharge process could be adjusted correspondingly, so that the electrical discharge machining procedure could be maintained in a predetermined target machining status.

(2) A debris removal unit could provide an external force to assist in removing debris remaining in a machining groove.

(3) A guide structure could correctly guide the external force provided by the debris removal unit to a current electrical discharge machining position of the electrical discharge machining procedure.

(4) The electrical discharge electrode could be used as a capacitive sensing element to provide a sensing capacitance value as an electrical discharge feedback signal in real time.

(5) An insulating sleeve covers the electrical discharge electrode and exposes an electrical discharge surface of the electrical discharge electrode in a machining feed direction, which could reduce kerf loss and improve a precision of electrical discharge machining, so it could effectively improve the problem that the traditional electrical discharge electrodes and a to-be-machined object are prone to unexpected damage.

(6) Covering the electrical discharge electrode with the insulating sleeve could make the electrical discharge electrode less shaken and could also enhance the external force (such as water flow or air flow) to achieve an effect of removing debris. The insulating sleeve could make the to-be-machined object (such as wafer) less shaken after cutting, reducing the risk of fragmentation. Moreover, the insulating sleeve could use the external force (such as water flow or air flow) for removing debris to reduce a friction between the insulating sleeve and the electrical discharge electrode to avoid damage to the electrical discharge electrode. In addition, the insulating sleeve could also provide an efficacy of local heating.

(7) The insulating sleeve has a gap, which not only improves an electrical discharge machining effect of the electrical discharge electrode, but also provides a debris removal function.

(8) A clamping element has a slit structure that could firmly clamp the to-be-machined object, and could effectively solve the problem that the traditional electrical discharge machining technologies cannot cut an overlapping area between the clamping element and the to-be-machined object, and a lock-in structure could further achieve efficacies of disassembly, assembly and adjustment.

(9) The clamping element could be connected or adhered to the to-be-machined object through a buffer member, which could effectively avoid wafer cracking that often occurs in the traditional ingot cutting technologies.

Note that the specification relating to the above embodiments should be construed as exemplary rather than as limitative of the present disclosure, with many variations and modifications being readily attainable by a person of average skill in the art without departing from the spirit or scope thereof as defined by the appended claims and their legal equivalents.

What is claimed is:

1. An electrical discharge machining apparatus for performing an electrical discharge machining procedure on at least one to-be-machined object, at least comprising:
at least one carrier for carrying the to-be-machined object, the to-be-machined object being defined with at least one machining target area; and
at least one electrical discharge machining unit, comprising at least one electrical discharge electrode and a power supply unit, wherein the power supply unit provides an electrical discharge energy to the electrical discharge electrode with an electrical discharge frequency, and the electrical discharge machining unit performs the electrical discharge machining procedure on the machining target area of the to-be-machined object through the electrical discharge electrode with at least one machining parameter, wherein the electrical discharge machining unit adjusts an actual output energy value correspondingly according to a changing status of the electrical discharge frequency or the electrical discharge energy during an electrical discharge process of the electrical discharge machining procedure, so that the electrical discharge machining procedure maintains in a target machining status.

2. The electrical discharge machining apparatus as claimed in claim 1, wherein the electrical discharge machining unit adjusts the electrical discharge frequency and/or the electrical discharge energy provided by the power supply unit in order to adjust the actual output energy value in real time when performing the electrical discharge machining procedure, so that the electrical discharge machining procedure is maintained in the target machining status.

3. The electrical discharge machining apparatus as claimed in claim 1, wherein the electrical discharge machining unit adjusts the actual output energy value in real time accordingly by adjusting the machining parameter.

4. The electrical discharge machining apparatus as claimed in claim 3, wherein the electrical discharge machining unit correspondingly adjusts the machining parameter according to an intrinsic or extrinsic characteristic of the to-be-machined object, so that the electrical discharge machining procedure is maintained in the target machining status.

5. The electrical discharge machining apparatus as claimed in claim 4, wherein there are a plurality of types of the machining parameter, and the electrical discharge machining procedure selects at least one of the types of the machining parameters for adjustment, so that the electrical discharge machining procedure is maintained in the target machining status.

6. The electrical discharge machining apparatus as claimed in claim 1, wherein the target machining status is selected from a group consisting of the cutting speed, material removal rate, material loss rate and surface roughness of the to-be-machined object, and disconnection frequency of the electrical discharge electrode.

7. The electrical discharge machining apparatus as claimed in claim 1, wherein the electrical discharge machining unit performs the electrical discharge machining procedure on the machining target area of the to-be-machined object at a preset temperature, and the preset temperature is less than or equal to 100 degrees Celsius.

8. The electrical discharge machining apparatus as claimed in claim 1, wherein the electrical discharge machining unit performs the electrical discharge machining procedure on the machining target area of the to-be-machined object in a temperature range, wherein the to-be-machined object has a substantially lowest resistivity in the temperature range.

9. The electrical discharge machining apparatus as claimed in claim 7, wherein the electrical discharge machining unit performs the electrical discharge machining procedure on the machining target area of the to-be-machined object in an aqueous solution.

10. The electrical discharge machining apparatus as claimed in claim 9, wherein the to-be-machined object is a semiconductor material.

11. The electrical discharge machining apparatus as claimed in claim 1, wherein the carrier further comprises at least one clamping element, the clamping element is a slit structure, and the clamping element exerts a force radially or axially on the to-be-machined object to fix the to-be-machined object.

12. The electrical discharge machining apparatus as claimed in claim 11, wherein a shape of a slit of the slit structure is selected from a group consisting of closed type without opening, single-sided opening type and double-sided opening type.

13. The electrical discharge machining apparatus as claimed in claim 11, wherein the clamping element is a fixed or detachable single-sided lock-in structure or double-sided lock-in structure for clamping the to-be-machined object.

14. The electrical discharge machining apparatus as claimed in claim 11, wherein the slit structure has one slit or a plurality of slits, and each of the slits has a same span or different spans.

15. The electrical discharge machining apparatus as claimed in claim 11, wherein the slit structure has one slit or a plurality of slits, and a spacing between the every two adjacent slits is the same or different.

16. The electrical discharge machining apparatus as claimed in claim 11, wherein the slit structure has at least one slit, and the slit has a non-equidistant span or an adjustable span.

17. The electrical discharge machining apparatus as claimed in claim 11, wherein the slit structure has a plurality of slits, and at least two of the slits in the slits are communicated to each other.

18. The electrical discharge machining apparatus as claimed in claim 11, wherein the clamping element and the to-be-machined object are partially connected or bonded to each other through a conductor or an insulator.

19. The electrical discharge machining apparatus as claimed in claim 18, wherein the conductor or the insulator is a solid medium, a soft medium or an adhesive.

20. The electrical discharge machining apparatus as claimed in claim 1, further comprising a debris removal unit for providing at least one external force to remove debris generated when the electrical discharge electrode performing the electrical discharge machining procedure on the to-be-machined object.

21. The electrical discharge machining apparatus as claimed in claim 20, wherein the external force is selected from one or more than one of a group consisting of air flow, water flow, ultrasonic oscillation, piezoelectric oscillation, suction force and magnetic force.

22. The electrical discharge machining apparatus as claimed in claim 20, wherein the removal unit further comprises a guide structure for guiding the external force to reach a machining groove on the machining target area of the to-be-machined object performed with the electrical discharge machining procedure by the electrical discharge electrode.

23. The electrical discharge machining apparatus as claimed in claim 22, wherein the guide structure manually or automatically changes position or angle of guiding the external force along with the electrical discharge electrode performing the electrical discharge machining procedure, so as to guide the external force to reach an electrical discharge machining position of the machining groove of the to-be-machined object in the electrical discharge machining procedure currently performed by the electrical discharge electrode.

24. The electrical discharge machining apparatus as claimed in claim 22, wherein the guide structure moves a position in the machining groove of the machining target area of the to-be-machined object along with the electrical discharge electrode, thereby moving in a synchronous filling manner to reach an electrical discharge machining position on the machining groove of the machining target area where the electrical discharge machining procedure has been completed.

25. The electrical discharge machining apparatus as claimed in claim 22, wherein the guide structure is an externally sealed baffle used for covering an area of the machining target area of the to-be-machined object that has not yet been processed by the electrical discharge machining procedure, and moving a position synchronously along with the electrical discharge electrode.

26. The electrical discharge machining apparatus as claimed in claim 22, wherein the guide structure is an interdigitated structure corresponding to the machining groove on the machining target area of the to-be-machined object.

27. The electrical discharge machining apparatus as claimed in claim 22, wherein the guide structure is used in conjunction with a telescopic mechanism, so as to automatically move synchronously along with the electrical discharge electrode to guide the external force.

28. The electrical discharge machining apparatus as claimed in claim 22, wherein the guide structure is used in conjunction with a sensing element for adjusting a guiding effect of the guide structure based on a sensing result of the sensing element.

29. The electrical discharge machining apparatus as claimed in claim 1, further comprising a temperature control unit for providing a heat source and/or a cold source when performing the electrical discharge machining procedure to directly or indirectly adjust a temperature of the to-be-machined object.

30. The electrical discharge machining apparatus as claimed in claim 29, wherein the heat source is infrared ray, microwave or electric heater.

31. The electrical discharge machining apparatus as claimed in claim 29, wherein the cold source is used in conjunction with an antifreeze agent to prevent a machining environment of the electrical discharge machining unit from freezing.

32. The electrical discharge machining apparatus as claimed in claim 29, wherein the temperature control unit has a temperature sensor to judge whether a machining environment of the to-be-machined object reaches a target temperature to maintain the machining environment at the target temperature.

33. The electrical discharge machining apparatus as claimed in claim 1, wherein a machining environment of the electrical discharge machining unit is added with ozone or bubbles, thereby improving a machining efficiency through oxidation, softening or bursting.

34. The electrical discharge machining apparatus as claimed in claim 1, wherein a material of the electrical discharge electrode is selected from a group consisting of copper, brass, molybdenum, tungsten, graphite, steel, aluminum, zinc, nickel and diamond.

35. The electrical discharge machining apparatus as claimed in claim 1, wherein an interior of the electrical discharge electrode is a metal layer, and the electrical discharge electrode has a dielectric material layer or a diamond layer covering an outer periphery of the metal layer.

36. The electrical discharge machining apparatus as claimed in claim 35, wherein during the electrical discharge process of the electrical discharge machining procedure, the electrical discharge electrode serves as a capacitive sensing element for providing a sensing capacitance value.

37. The electrical discharge machining apparatus as claimed in claim 1, wherein when a number of at least either the electrical discharge electrode or the to-be-machined object is a plurality, the electrical discharge machining procedure has a plurality of machining feed speeds correspondingly, and the electrical discharge machining unit uses a slowest one among the machining feed speeds as a common machining feed speed.

38. The electrical discharge machining apparatus as claimed in claim 37, wherein the carrier is a movable carrier, and the carrier uses the common machining feed speed as a moving speed.

39. The electrical discharge machining apparatus as claimed in claim 1, wherein a number of the electrical discharge electrode is a plurality, and each of the electrical discharge electrodes has an independently controlled machining feed speed.

40. The electrical discharge machining apparatus as claimed in claim 1, wherein numbers of the electrical discharge electrode and the to-be-machined object are a plurality, and the electrical discharge electrodes perform the electrical discharge machining procedure on the same to-be-machined object or the different to-be-machined objects.

41. The electrical discharge machining apparatus as claimed in claim 1, wherein the electrical discharge machining unit further comprises an insulating sleeve, and the insulating sleeve is sleeved on an outer side of the electrical discharge electrode and exposes at least one surface of the electrical discharge electrode in a machining feed direction, thereby using the surface as an electrical discharge surface when the electrical discharge electrode performs the electrical discharge process.

42. The electrical discharge machining apparatus as claimed in claim 41, wherein an electrical discharge area formed by the electrical discharge surface exposed by the electrical discharge electrode during performing the electrical discharge process is substantially greater than a cross section of the insulating sleeve.

43. The electrical discharge machining apparatus as claimed in claim 41, wherein relative positions of the insulating sleeve and the electrical discharge electrode in a machining feed direction of the electrical discharge machining procedure are fixed, and relative positions of the insulating sleeve and the electrical discharge electrode in a tension direction of the electrical discharge electrode are movable.

44. The electrical discharge machining apparatus as claimed in claim 41, wherein the insulating sleeve comprises a bottom plate and two side walls, the two side walls are located at two ends of the bottom plate to form a trough, an interior of the trough forms a chamber for accommodating the electrical discharge electrode, and the trough has an opening communicated to the chamber for exposing the electrical discharge surface of the electrical discharge electrode located in the chamber.

45. The electrical discharge machining apparatus as claimed in claim 41, wherein the insulating sleeve is sleeved on an outer side of the electrical discharge electrode along a tension direction of the electrical discharge electrode, and the insulating sleeve has one notch or a plurality of notches for providing a function of draining water or removing debris in the electrical discharge machining procedure.

46. The electrical discharge machining apparatus as claimed in claim 1, wherein the carrier further comprises at least one clamping element, and a degree of conformity between a clamping surface of the clamping element and a contour of the to-be-machined object is correspondingly changed based on a degree of clamping between the clamping element and the to-be-machined object in order to correspondingly change a degree of adhesion between the clamping surface of the clamping element and the contour of the to-be-machined object.

47. The electrical discharge machining apparatus as claimed in claim 1, wherein the power supply unit of the electrical discharge machining unit is integratedly or detachably configured on the electrical discharge machining apparatus for supplying a power source of the electrical discharge energy to the to-be-machined object.

48. The electrical discharge machining apparatus as claimed in claim 1, further comprising a non-destructive detection device for detecting the to-be-machined object before, during or after performing the electrical discharge machining procedure.

49. The electrical discharge machining apparatus as claimed in claim 1, wherein the electrical discharge machining unit further comprises a vibration measuring unit for measuring a vibration value of the electrical discharge electrode.

50. The electrical discharge machining apparatus as claimed in claim 1, wherein the electrical discharge machining unit further comprises a tension measuring unit for measuring a tension value of the electrical discharge electrode.

51. An electrical discharge machining method, using the electrical discharge machining apparatus in claim 1, comprising following steps of:
providing a carrier;
providing a to-be-machined object, wherein the to-be-machined object is defined with a machining target area, and the to-be-machined object is carried on the carrier; and
providing an electrical discharge machining unit, the electrical discharge machining unit comprising at least one electrical discharge electrode and a power supply unit, wherein the power supply unit provides an electrical discharge energy to the electrical discharge electrode with an electrical discharge frequency, and the electrical discharge machining unit performs an electrical discharge machining procedure on the machining target area of the to-be-machined object through the electrical discharge electrode with a machining parameter, wherein the electrical discharge machining unit adjusts an actual output energy value correspondingly according to a changing status of the electrical discharge frequency or the electrical discharge energy during an electrical discharge process of the electrical discharge machining procedure, so that the electrical discharge machining procedure maintains in a target machining status.
